(19) United States
(12) Patent Application Publication
(10) Pub. No.: US 2026/0215306 A1
(43) Pub. Date: Jul. 23, 2026

(54) SEMICONDUCTOR STRUCTURE AND METHOD FOR FORMING THE SAME

(71) Applicant: Taiwan Semiconductor Manufacturing Company, Ltd., Hsinchu (TW)

(72) Inventors: Kan-Ju YANG, Hsinchu (TW); Wen-Yi LIN, Hsinchu (TW); Zhihua ZOU, Taipei City (TW); Hsing-Chieh LEE, Hsinchu city (TW)

(21) Appl. No.: 19/033,908

(22) Filed: Jan. 22, 2025

(51) Int. Cl. H01L 23/00; H01L 21/48; H01L 21/683; H01L 23/498; H01L 23/538; H01L 23/544; H01L 25/065; H01L 25/18; H10B 80/00; H10D 80/30

(52) U.S. Cl. CPC H10W 70/685; H10W 46/00; H10W 70/05; H10W 70/095; H10W 70/611; H10W 70/65; H10W 90/401; H10W 90/701; H10B 80/00; H10D 80/30; H10P 72/74; H10P 72/744; H10W 46/301; H10W 70/09; H10W 70/60; H10W 70/6528; H10W 90/00

(57) ABSTRACT

A method for forming a semiconductor structure is provided. The method includes forming a first redistributing structure over a first carrier, detaching the first redistributing structure from the first carrier, forming a dielectric structure over a substrate, planarizing the dielectric structure to form a planarized surface, and bonding a first surface of the first redistributing structure to the planarized surface of the dielectric structure, wherein the first redistributing structure is in contact with the dielectric structure.

### BACKGROUND

Semiconductor devices are used in a variety of electronic applications, such as, for example, personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. However, as the minimum features sizes are reduced, additional problems arise that should be addressed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A to FIG. 1P are schematic views of a process for forming a redistributing structure, in accordance with some embodiments.

FIG. 1Q is an alternative configuration of a redistributing structure, in accordance with some embodiments.

FIG. 2A to FIG. 2K are schematic views of a process for forming a semiconductor chip, in accordance with some embodiments.

FIG. 3A to FIG. 3I are schematic views of a process for forming a semiconductor package structure, in accordance with some embodiments.

FIG. 4A to FIG. 4E are schematic views of a process for forming a semiconductor chip, in accordance with some embodiments.

FIG. 5A to FIG. 5F are schematic views of a process for forming a semiconductor chip, in accordance with some embodiments.

FIG. 6A to FIG. 6F are schematic views of a process for forming a semiconductor chip, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The terms “about” and “substantially” typically mean +/−20% of the stated value, more typically +/−10% of the stated value, more typically +/−5% of the stated value, more typically +/−3% of the stated value, more typically +/−2% of the stated value, more typically +/−1% of the stated value and even more typically +/−0.5% of the stated value. The stated value of the present disclosure is an approximate value. When there is no specific description, the stated value includes the meaning of “about” or “substantially”.

Use of ordinal terms such as “first”, “second”, etc., in the claims to modify a claim element does not by itself connote any priority, precedence, or order of one claim element over another or the temporal order in which acts of a method are performed, but are used merely as labels to distinguish one claim element having a certain name from another element having the same name (but for use of the ordinal term) to distinguish the claim elements.

A semiconductor structure and method for forming the same are provided in some embodiments of the present disclosure. Such semiconductor structure includes a redistributing structure having reduced interface roughness between dielectric sublayers. In some embodiments, the redistributing structure is pre-made on a carrier, and then bonded to the underneath elements for forming the semiconductor structure, thereby reducing the number of thermal process cycles. Therefore, problems occurred during thermal process such as warpage and residue stress may be mitigated.

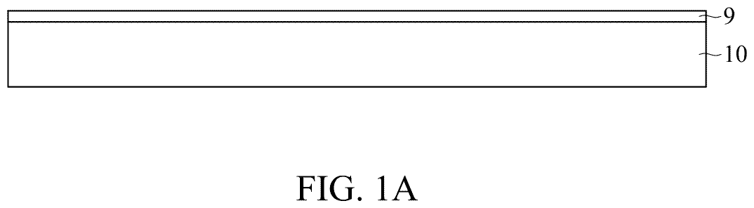

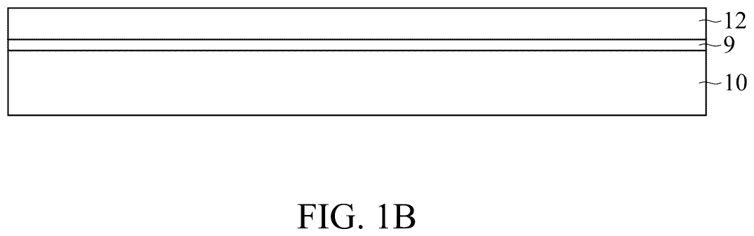

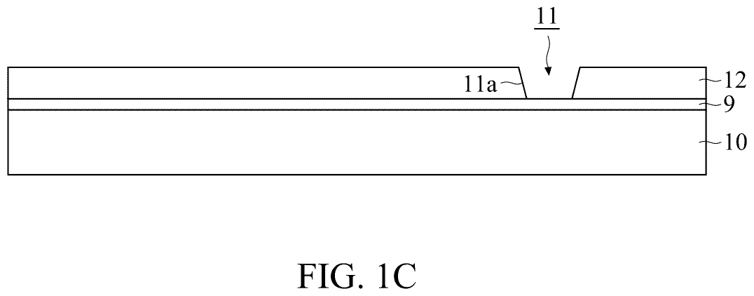

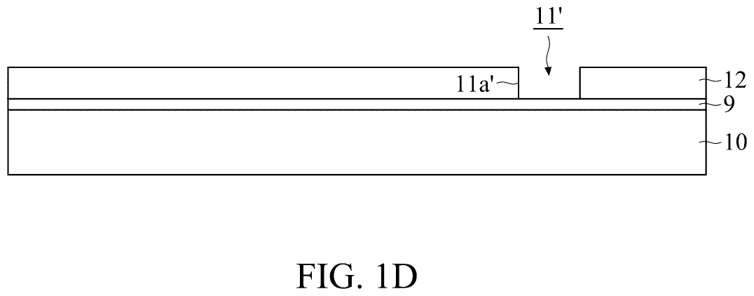

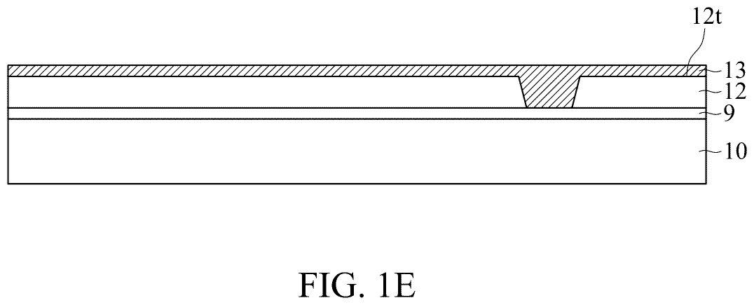

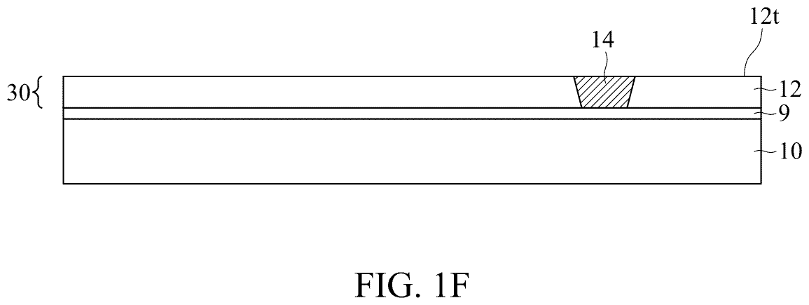

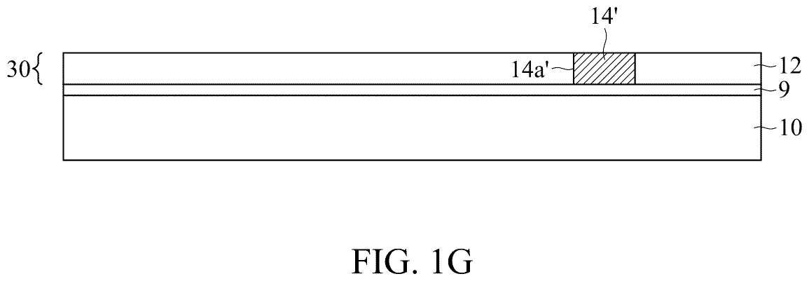

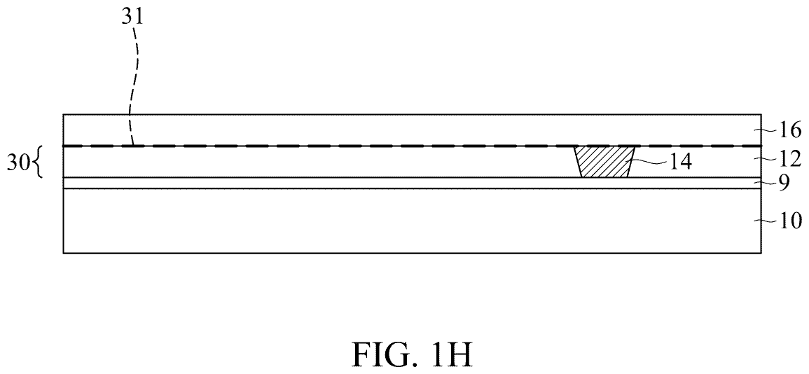

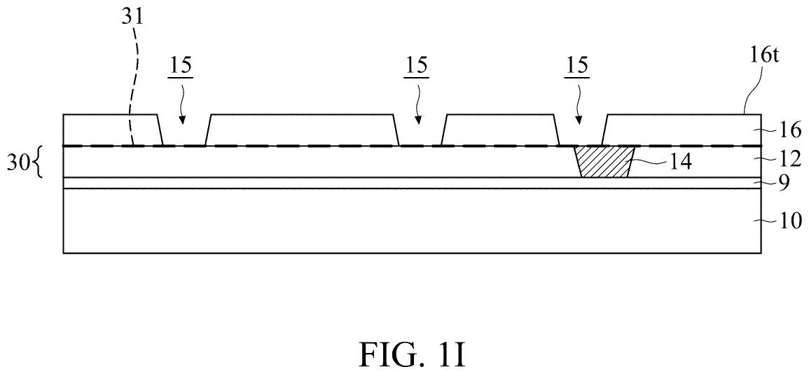

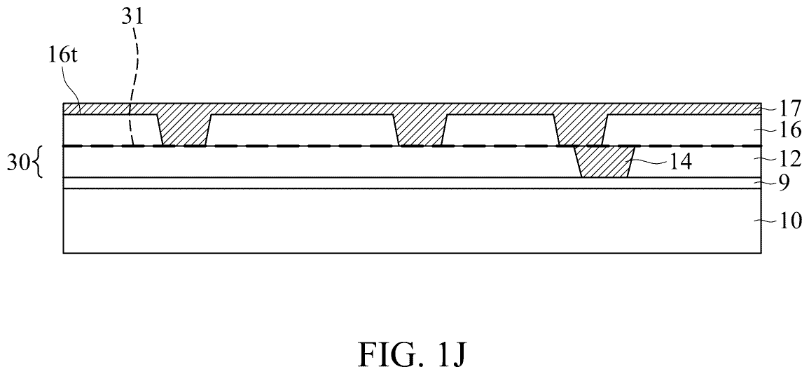

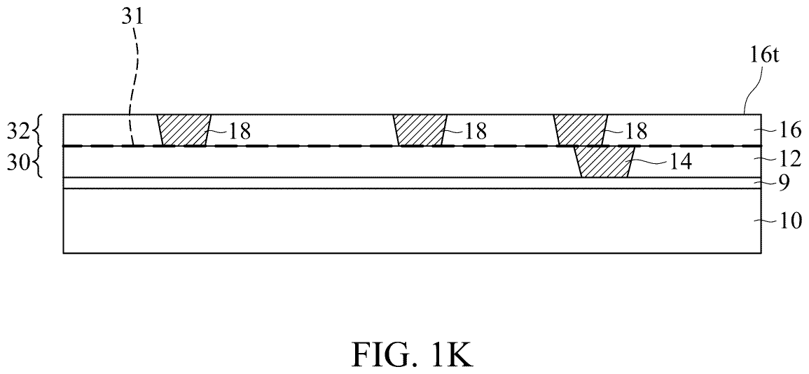

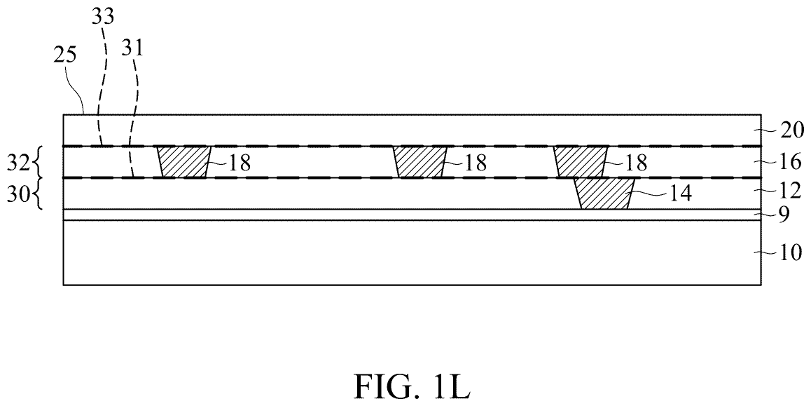

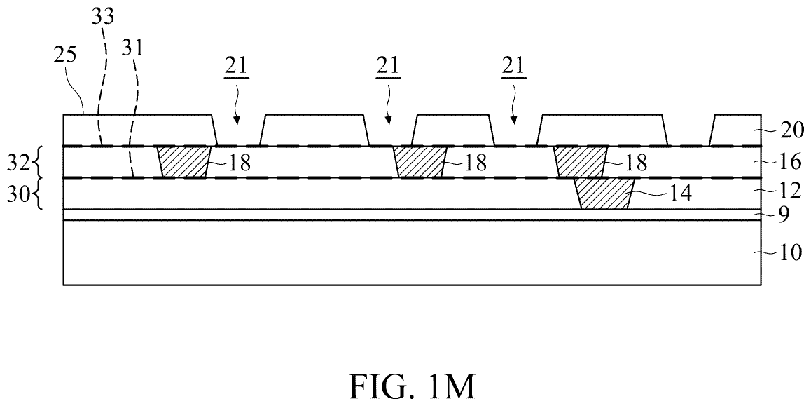

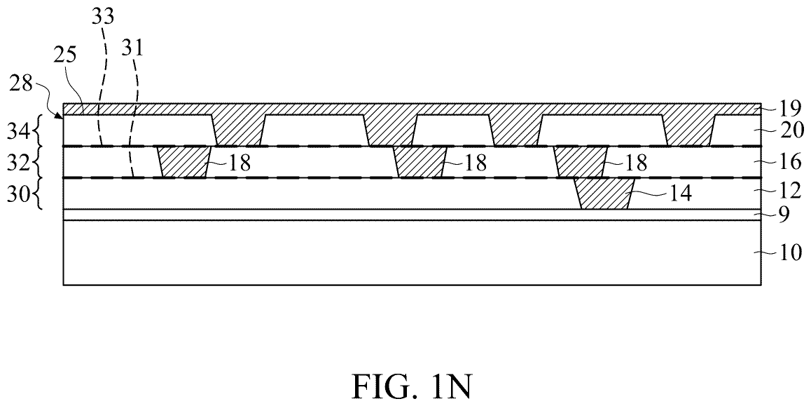

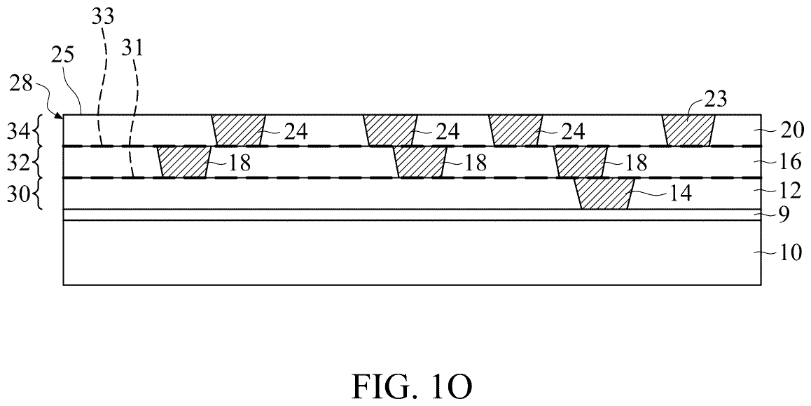

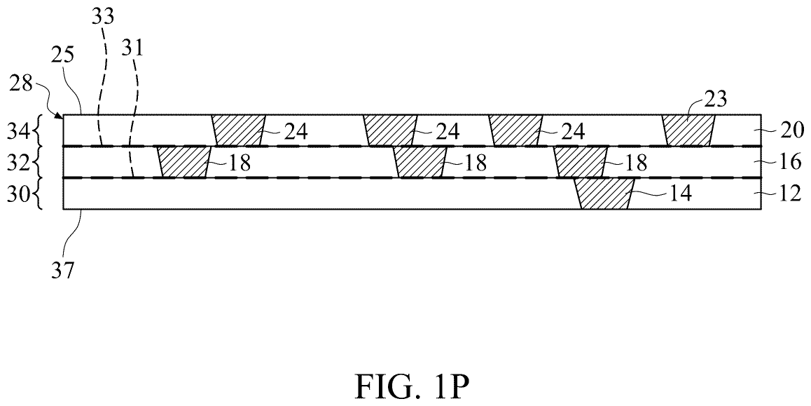

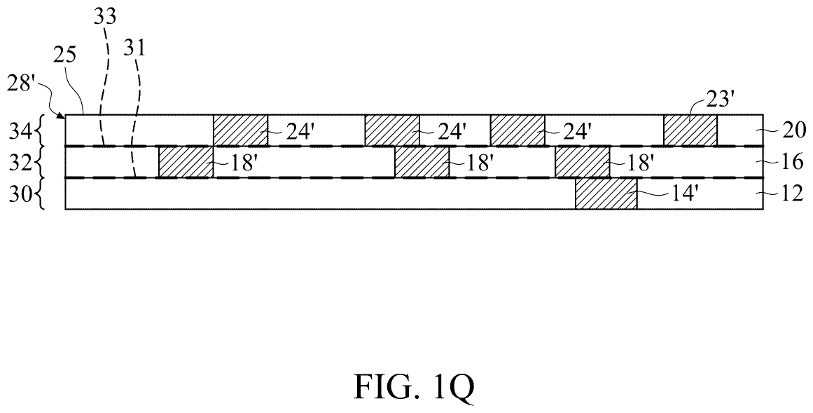

FIG. 1A to FIG. 1P are schematic views of a process for forming a redistributing structure, in accordance with some embodiments. As shown in FIG. 1A, a carrier 10 having a release film 9 over the carrier 10 is provided in some embodiments. The carrier 10 may be made of silicon (Si) or other semiconductor materials, such as germanium (Ge) or silicon germanium (SiGe). In some embodiments, the carrier 10 may include a compound semiconductor, such as silicon carbide (SiC), silicon phosphide (SiP), gallium arsenide (GaAs), gallium phosphide (GaP), indium phosphide (InP), indium arsenide (InAs), indium antimonide (InSb), zinc oxide (ZnO), zinc selenide (ZnSe), zinc sulfide (ZnS), zinc telluride (ZnTe), cadmium selenide (CdSe), cadmium sulfide (CdS), and/or cadmium telluride (CdTe); an alloy semiconductor, such as silicon germanium (SiGe), silicon phosphorus carbide (SiPC), gallium arsenic phosphide (GaAsP), aluminum indium arsenide (AlInAs), aluminum gallium arsenide (AlGaAs), gallium indium arsenide (GaInAs), gallium indium phosphide (GaInP), and/or gallium indium arsenic phosphide (GaInAsP); other group III-V materials; other group II-V materials; or combinations thereof. In some embodiments, the carrier 10 may be a glass substrate or any other substrate material.

In some embodiments, the release film 9 may be formed of a polymer-based material and/or an epoxy-based thermal-release material (such as a Light-To-Heat-Conversion (LTHC) material), which is capable of being decomposed under radiation such as a laser beam, so that the carrier 10 may be de-bonded from the overlying structures that will be formed in subsequent processes. In accordance with some embodiments of the present disclosure, the release film 9 is applied on the carrier 10 through coating.

As shown in FIG. 1B, a dielectric layer 12 is formed over the release film 9. In some embodiments, the dielectric layer 12 is formed using a deposition method such as plasma-enhanced chemical vapor deposition (PECVD), low-pressure chemical vapor deposition (LPCVD), or the like. In some embodiments, the dielectric layer 12 may be made of a polymer material such as epoxy, polyimide, polybenzoxazole (PBO), benzocyclobutene (BCB), solder resist (SR), ABF film, and the like, in accordance with some embodiments. In some embodiments, the dielectric layer 12 is made of a photosensitive material and may undergo chemical reactions when exposed to light.

In some embodiments, the dielectric layer 12 may have a coefficient of thermal expansion (CTE) of less than 30 ppm/° C. below its glass transition temperature (Tg), which is greater than about 280° C. In some embodiments, the dielectric layer 12 has a Young's modulus greater than about 4 GPa. In some embodiments, the dielectric layer 12 has a dielectric constant (dk) less than about 3 F/m. In some embodiments, the dielectric layer 12 has a dissipation factor (df) less than about 0.005.

As shown in FIG. 1C, openings 11 are formed in the dielectric layer 12 to expose the carrier 10 from the openings 11. For example, a patterned mask (e.g., photoresist or a combination of photoresist and hard mask) may be formed over the dielectric layer 12, and an etching process such as a dry etching process and/or a wet etching process may be performed to form the openings 11 according to the pattern of the patterned mask. In some embodiments, the openings 11 have an inclined sidewall 11a.

FIG. 1D shows an alternative configuration of forming openings 11′ in the dielectric layer 12, in accordance with some embodiments. The openings 11′ may be formed by laser drilling. Therefore, the openings 11′ may have a vertical sidewall 11a′.

As shown in FIG. 1E, a conductive layer 13 is formed over a top surface 12t of the dielectric layer 12 and in the opening 11. For example, a liner layer, which may include a barrier layer, an adhesion layer, and/or a seed layer, may be formed in the opening 11 by a deposition method, such as chemical vapor deposition (CVD), physical vapor deposition (PVD), or atomic layer deposition (ALD). The liner may include Tungsten (W), aluminum (Al), copper (Cu), titanium (Ti), tantalum (Ta), titanium nitride (TiN), tantalum nitride (TaN), alloys or multiple layers thereof, or the like. In some embodiments, a low-resistance conductive material is formed over the liner and fills the remaining portions of the opening 11 in the dielectric layer 12. For example, the low-resistance conductive material may be formed by electroplating, electroless plating, CVD, PVD, a combination thereof, or the like.

As shown in FIG. 1F, excess materials of the liner layer and the low-resistance conductive material over the top surface 12t of the dielectric layer 12 may be removed by a planarization process, such as chemical mechanical polishing (CMP) or a mechanical grinding process. The liner layer and the low-resistance conductive material in the openings 11 of the dielectric layer 12 may form the conductive features 14. In some embodiments, the conductive features 14 may include metal vias, metal lines, and/or metal pads. In some embodiments of the present disclosure, the dielectric layer 12 and the conductive features 14 may have a coplanar top surface for providing a flat platform for overlying layers being formed over the dielectric layer 12 and the conductive features 14. The dielectric layer 12 and the conductive features 14 may be collectivity called as a sublayer 30. In some embodiments, the top surface 12t has a peak-to-valley (PV) flatness between about 5 nm and about 100 nm, such as between about 10 nm and about 50 nm. The peak-to-valley flatness may be defined as the difference between the highest peak and the lowest valley on the surface or the interface.

FIG. 1G shows an alternative configuration of forming conductive features 14′ in the openings 11′ shown in FIG. 1D, in accordance with some embodiments. Since the openings 11′ have a vertical sidewall 11a′, the conductive features 14′ in the openings 11′ may have a vertical sidewall 14a′.

Afterwards, as shown in FIG. 1H, a dielectric layer 16 is formed over the dielectric layer 12, and an interface 31 is between the dielectric layer 12 and the dielectric layer 16. In some embodiments, the dielectric layer 16 is formed using a deposition method such as plasma-enhanced chemical vapor deposition (PECVD), low-pressure chemical vapor deposition (LPCVD), or the like. In some embodiments, the dielectric layer 16 may be made of a polymer material such as epoxy, polyimide, polybenzoxazole (PBO), benzocyclobutene (BCB), solder resist (SR), ABF film, and the like, in accordance with some embodiments. In some embodiments, the dielectric layer 16 is made of a photosensitive material and may undergo chemical reactions when exposed to light. In some embodiments, the interface 31 between the dielectric layer 12 and the dielectric layer 16 has a peak-to-valley (PV) flatness between about 5 nm and about 100 nm, such as between about 10 nm and about 50 nm. The term “peak-to-valley flatness” in the present disclosure may be defined as the difference between the highest peak and the lowest valley on a surface or an interface. This is because the top surface 12t is planarized by a chemical mechanical polishing (CMP) process or a mechanical grinding process, leading to a lower peak-to-valley flatness. Therefore, problems occurred during thermal process such as warpage and residue stress may be mitigated.

In some embodiments, the dielectric layer 16 may have a coefficient of thermal expansion (CTE) of less than 30 ppm/° C. below its glass transition temperature (Tg), which is greater than about 280° C. In some embodiments, the dielectric layer 16 has a Young's modulus greater than about 4 GPa. In some embodiments, the dielectric layer 16 has a dielectric constant (dk) less than about 3 F/m. In some embodiments, the dielectric layer 16 has a dissipation factor (df) less than about 0.005.

As shown in FIG. 1I, openings 15 are formed in the dielectric layer 16 to at least partially expose the dielectric layer 12 and the conductive features 14 from the openings 15. For example, a patterned mask (e.g., photoresist or a combination of photoresist and hard mask) may be formed over the dielectric layer 16, and an etching process such as a dry etching process and/or a wet etching process may be performed to form the openings 15 according to the pattern of the patterned mask.

As shown in FIG. 1J, a conductive layer 17 is formed over a top surface 16t of the dielectric layer 16 and in the opening 15. For example, a liner layer, which may include a barrier layer, an adhesion layer, and/or a seed layer, may be formed in the opening 15 by a deposition method, such as chemical vapor deposition (CVD), physical vapor deposition (PVD), or atomic layer deposition (ALD). The liner may include Tungsten (W), aluminum (Al), copper (Cu), titanium (Ti), tantalum (Ta), titanium nitride (TiN), tantalum nitride (TaN), alloys or multiple layers thereof, or the like. In some embodiments, a low-resistance conductive material is formed over the liner and fills the remaining portions of the opening 15 in the dielectric layer 16. For example, the low-resistance conductive material may be formed by electroplating, electroless plating, CVD, PVD, a combination thereof, or the like.

As shown in FIG. 1K, excess materials of the liner layer and the low-resistance conductive material over the top surface 16t of the dielectric layer 16 may be removed by a planarization process, such as chemical mechanical polishing (CMP) or a mechanical grinding process. The liner layer and the low-resistance conductive material in the openings 15 of the dielectric layer 16 may form the conductive features 18. In some embodiments, the conductive features 18 may include metal vias and/or metal lines. In some embodiments, the dielectric layer 16 and the conductive features 18 may have a coplanar top surface for providing a flat platform for overlying layers being formed over the dielectric layer 16 and the conductive features 18. In some embodiments of the present disclosure, the dielectric layer 16 and the conductive features 18 may be collectivity called as a sublayer 32. In some embodiments, the top surface 16t has a peak-to-valley (PV) flatness between about 5 nm and about 100 nm, such as between about 10 nm and about 50 nm.

Afterwards, as shown in FIG. 1L, a dielectric layer 20 is formed over the dielectric layer 16, and an interface 33 is between the dielectric layer 16 and the dielectric layer 20. In some embodiments, the dielectric layer 20 is formed using a deposition method such as plasma-enhanced chemical vapor deposition (PECVD), low-pressure chemical vapor deposition (LPCVD), or the like. In some embodiments, the dielectric layer 20 may be made of a polymer material such as epoxy, polyimide, polybenzoxazole (PBO), benzocyclobutene (BCB), solder resist (SR), ABF film, and the like, in accordance with some embodiments. In some embodiments, the dielectric layer 20 is made of a photosensitive material and may undergo chemical reactions when exposed to light. In some embodiments, the interface 33 between the dielectric layer 16 and the dielectric layer 20 has a peak-to-valley (PV) flatness between about 5 nm and about 100 nm, such as between about 10 nm and about 50 nm. This is because the top surface 16t is planarized by a chemical mechanical polishing (CMP) process or a mechanical grinding process, leading to a lower peak-to-valley flatness. Therefore, problems occurred during thermal process such as warpage and residue stress may be mitigated.

In some embodiments, the dielectric layer 20 may have a coefficient of thermal expansion (CTE) of less than 30 ppm/° C. below its glass transition temperature (Tg), which is greater than about 280° C. In some embodiments, the dielectric layer 20 has a Young's modulus greater than about 4 GPa. In some embodiments, the dielectric layer 20 has a dielectric constant (dk) less than about 3 F/m. In some embodiments, the dielectric layer 20 has a dissipation factor (df) less than about 0.005.

As shown in FIG. 1M, openings 21 are formed in the dielectric layer 20 to expose the dielectric layer 16 and the conductive features 24 from the openings 21. For example, a patterned mask (e.g., photoresist or a combination of photoresist and hard mask) may be formed over the dielectric layer 20, and an etching process such as a dry etching process and/or a wet etching process may be performed to form the openings 21 according to the pattern of the patterned mask.

As shown in FIG. 1N, a conductive layer 19 is formed over a top surface 25 of the dielectric layer 20 and in the openings 21. For example, a liner layer, which may include a barrier layer, an adhesion layer, and/or a seed layer, may be formed in the openings 21 by a deposition method, such as chemical vapor deposition (CVD), physical vapor deposition (PVD), or atomic layer deposition (ALD). The liner may include Tungsten (W), aluminum (Al), copper (Cu), titanium (Ti), tantalum (Ta), titanium nitride (TiN), tantalum nitride (TaN), alloys or multiple layers thereof, or the like. In some embodiments, a low-resistance conductive material is formed over the liner and fills the remaining portions of the openings 21 in the dielectric layer 20. For example, the low-resistance conductive material may be formed by electroplating, electroless plating, CVD, PVD, a combination thereof, or the like.

As shown in FIG. 1O, excess materials of the liner layer and the low-resistance conductive material over the top surface 25 of the dielectric layer 20 may be removed by a planarization process, such as chemical mechanical polishing (CMP) or a mechanical grinding process. The liner layer and the low-resistance conductive material in the openings 21 of the dielectric layer 20 may form the conductive features 24. In some embodiments, the conductive features 24 may include metal vias, metal lines, and/or metal pads. In some embodiments, the conductive features 24 are electrically connected to the conductive features 14 through the conductive features 18. In some embodiments, the dielectric layer 20 and the conductive features 24 may have a coplanar top surface for providing a flat platform for overlying layers being formed over the dielectric layer 20 and the conductive features 24. The dielectric layer 20 and the conductive features 24 may be collectivity called as a sublayer 34. The sublayers 30, 32, and 34 may be collectivity called as a redistributing structure 28.

In some embodiments, an alignment mark 23 is formed in the dielectric layer 20 and exposed from a top surface 25 of the dielectric layer 20. In some embodiments, the alignment mark 23 is formed with the same process of forming the conductive features 24. In some embodiments, the alignment mark 23 is electrically isolated from the conductive features 14, 18, and 24. The alignment mark 23 is used for subsequent alignment process.

In FIG. 1P, the carrier 10 is then de-bonded (detached) from the redistributing structure 28, for example, by projecting UV light or a laser beam, which penetrates through the carrier 10, on the release film 9. The release film 9 decomposes under the heat of the UV light or the laser beam. The remained redistributing structure 28 may then be de-bonded from the carrier 10.

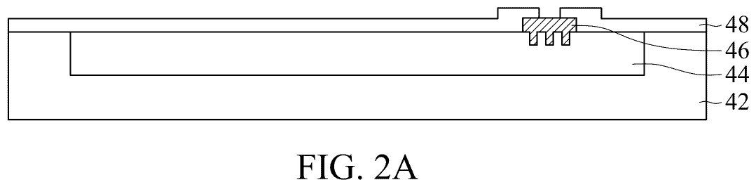

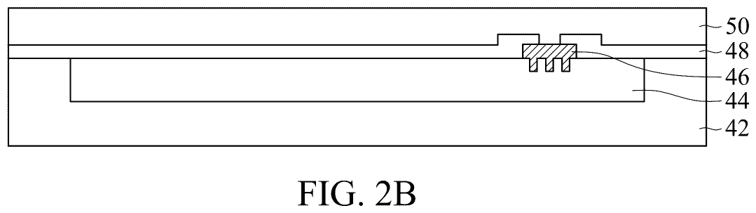

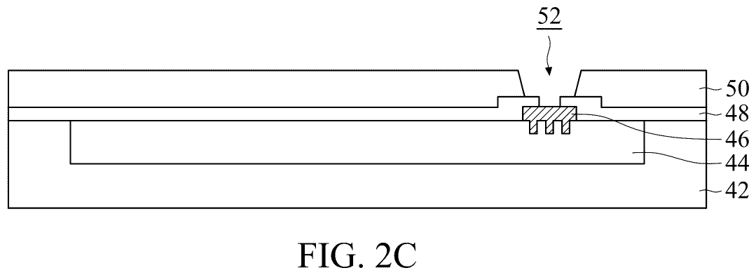

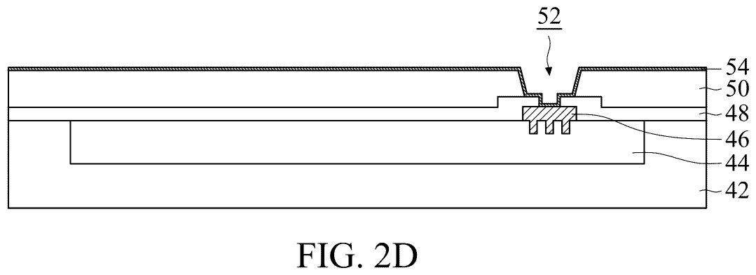

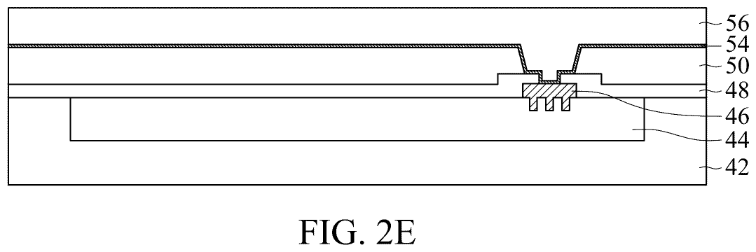

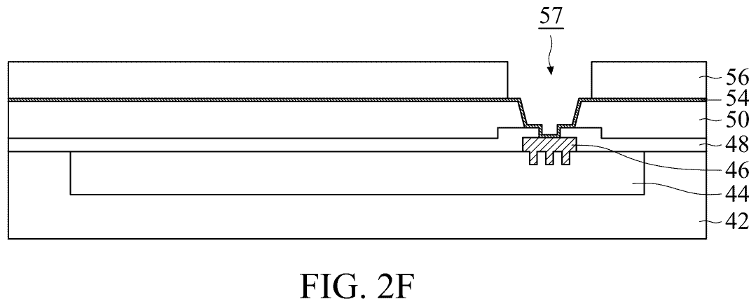

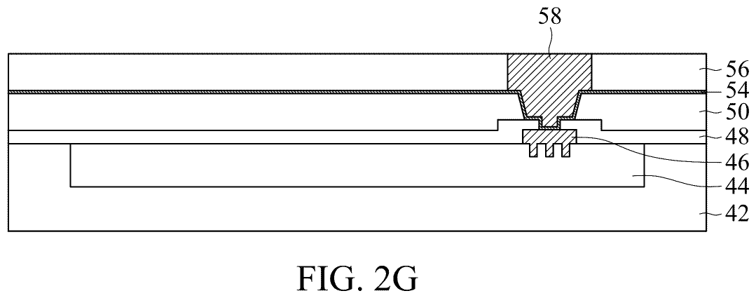

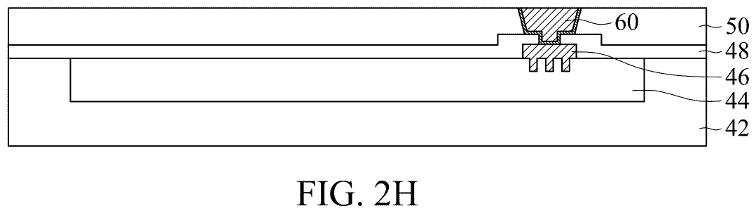

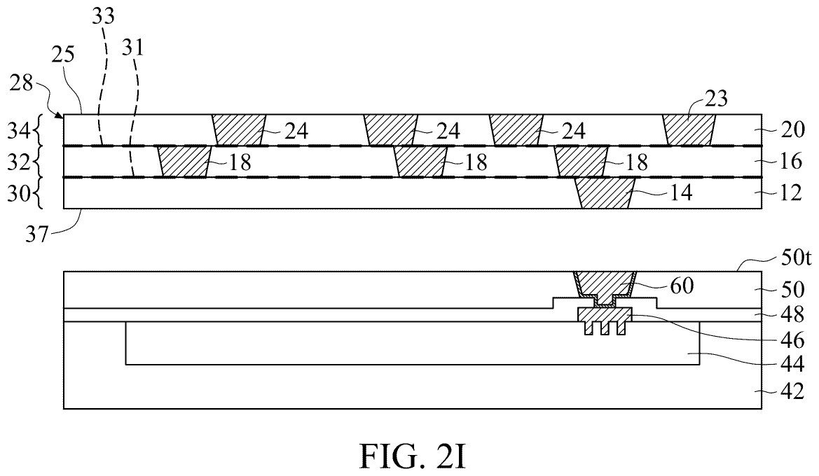

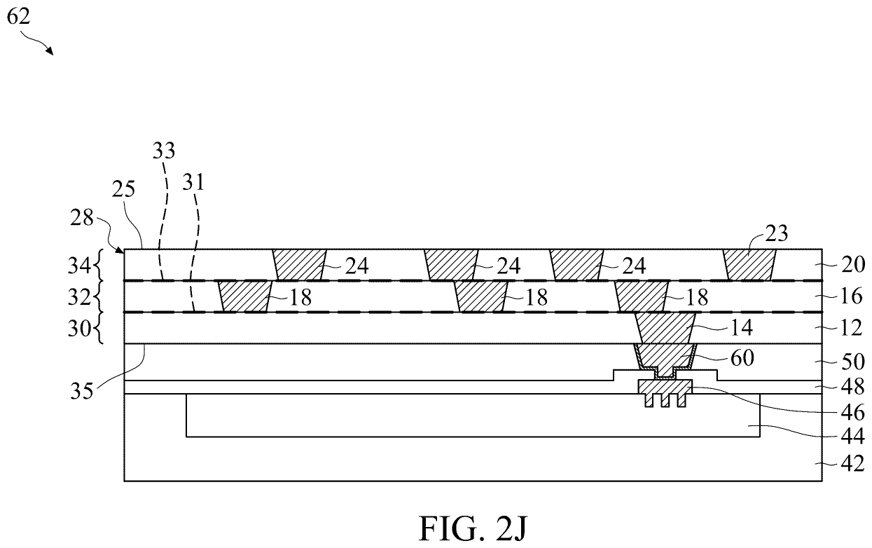

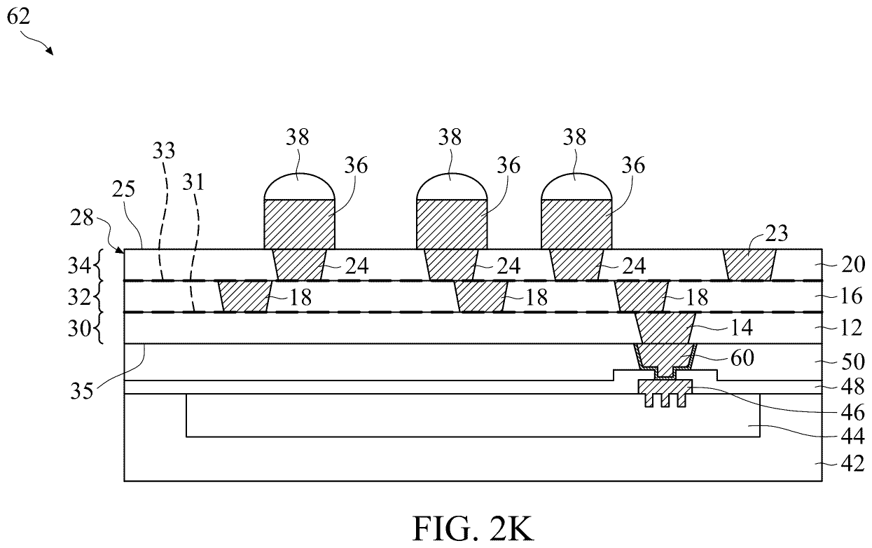

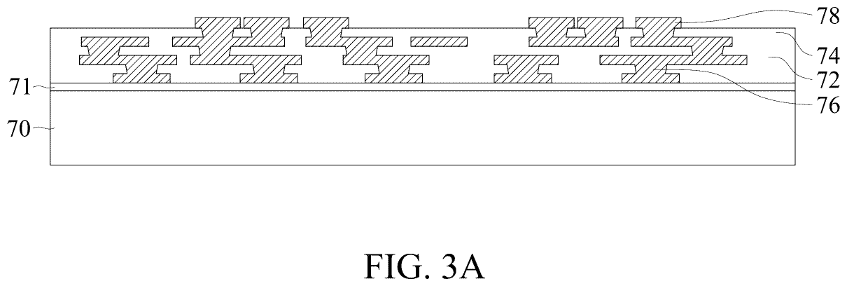

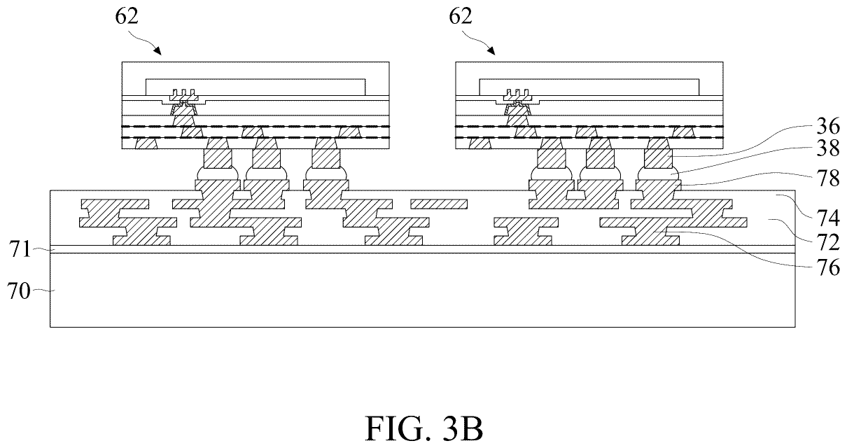

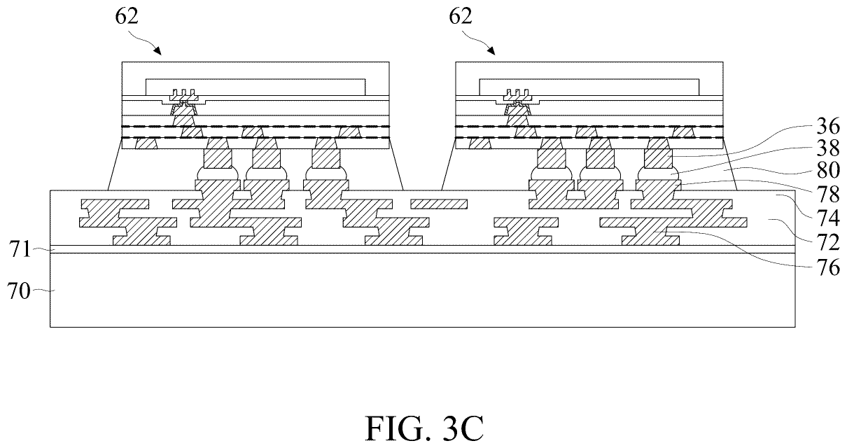

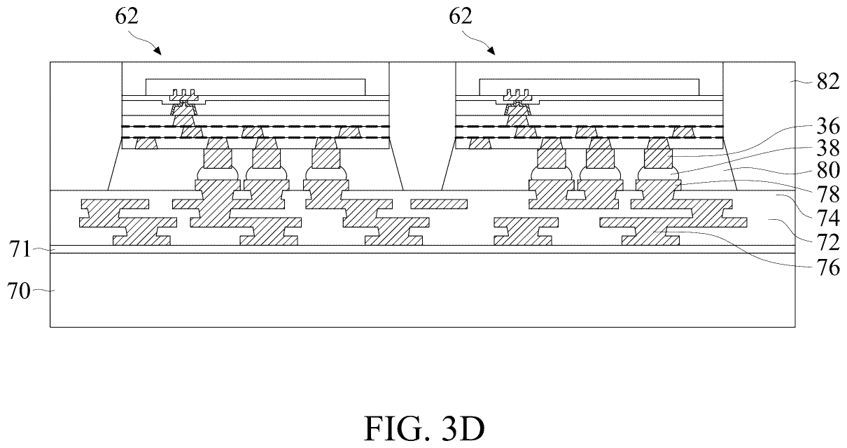

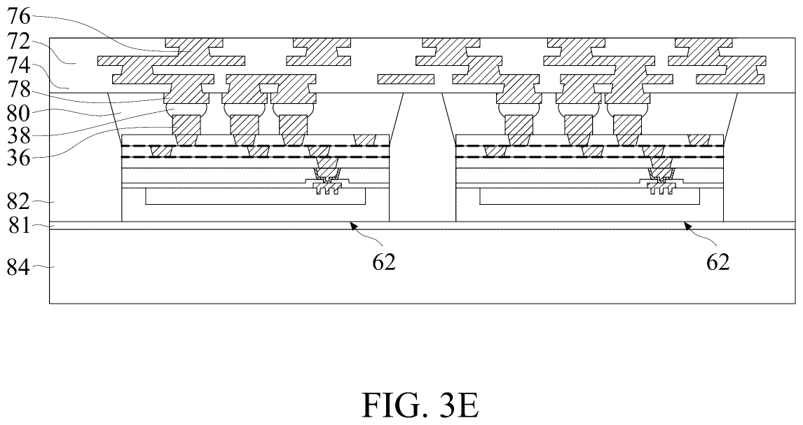

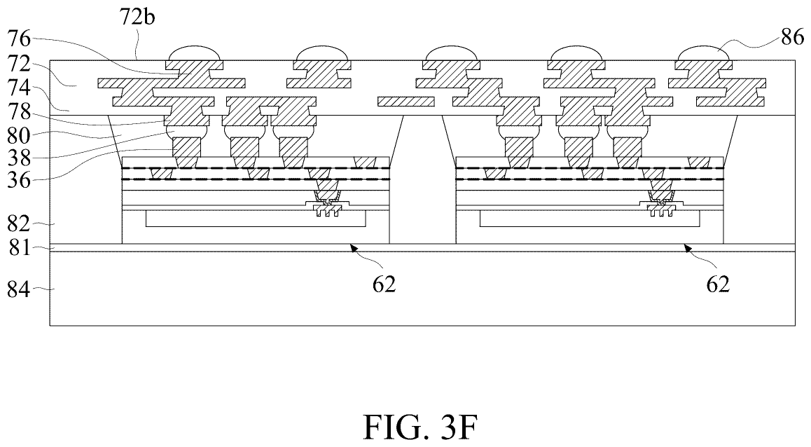

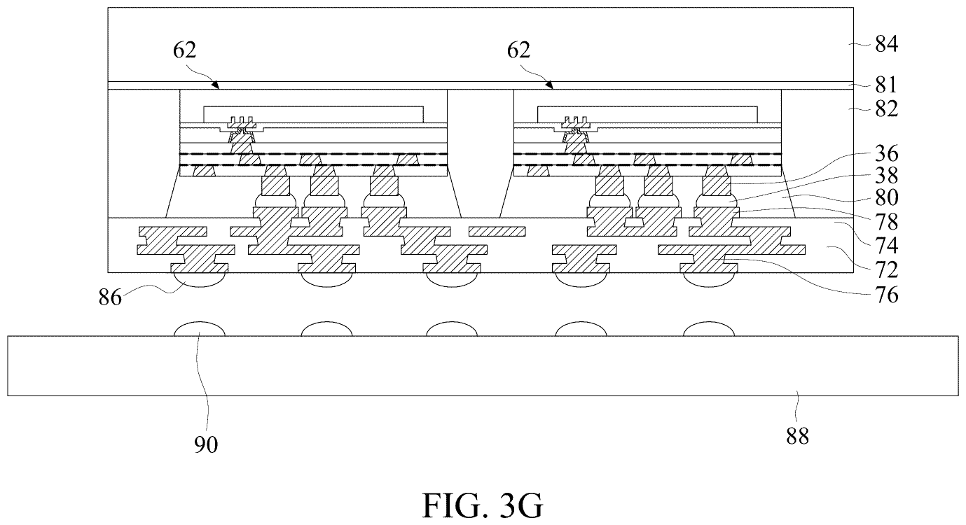

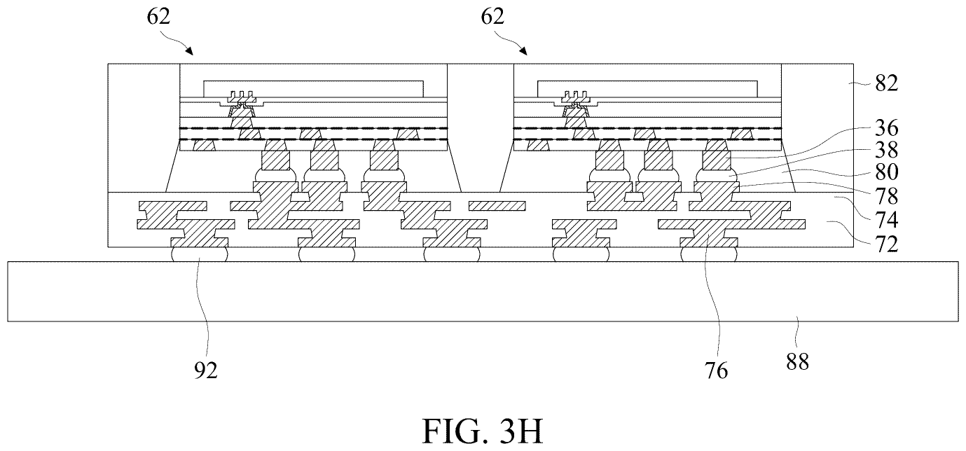

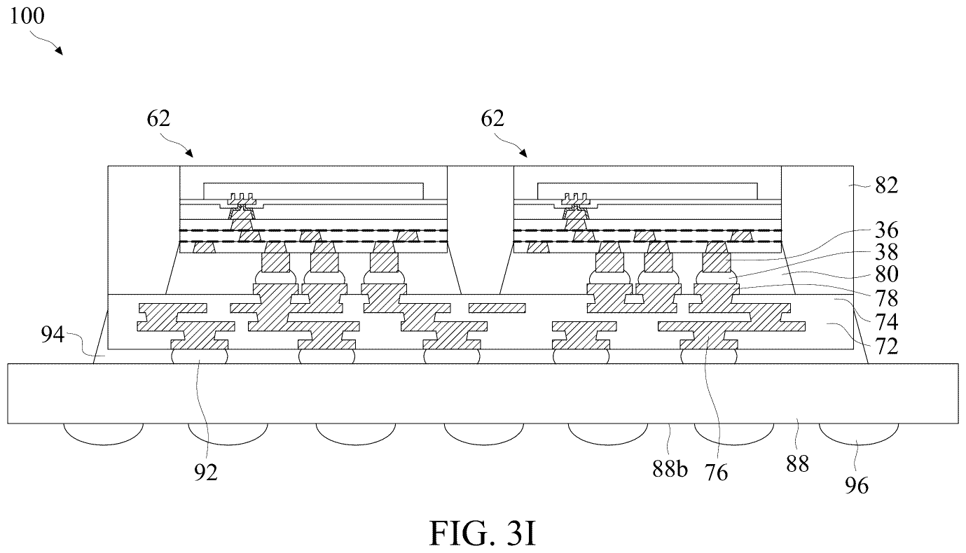

FIG. 1Q is an alternative configuration of a redistributing structure 28′, in accordance with some embodiments. In some embodiments, the conductive features 14′, 18′, and 24′ of the redistributing structure 28′ are formed by laser drilling, thereby having vertical sidewalls. It should be noted that the redistributing structure 28 in subsequent processes (such as the processes shown in FIG. 2A to FIG. 2K and FIG. 3A to FIG. 3I) may be replaced by the redistributing structure 28′, and the detailed processes will not be described again for simplicity.

FIG. 2A to FIG. 2K are schematic views of a process for forming a semiconductor chip 62, in accordance with some embodiments of the present disclosure. As shown in FIG. 2A, a substrate 42 is provided. In some embodiments, the substrate 42 may be made of silicon (Si) or other semiconductor materials, such as germanium (Ge) or silicon germanium (SiGe). In some embodiments, the substrate 42 may include a compound semiconductor, such as silicon carbide (SiC), silicon phosphide (SiP), gallium arsenide (GaAs), gallium phosphide (GaP), indium phosphide (InP), indium arsenide (InAs), indium antimonide (InSb), zinc oxide (ZnO), zinc selenide (ZnSe), zinc sulfide (ZnS), zinc telluride (ZnTe), cadmium selenide (CdSe), cadmium sulfide (CdS), and/or cadmium telluride (CdTe); an alloy semiconductor, such as silicon germanium (SiGe), silicon phosphorus carbide (SiPC), gallium arsenic phosphide (GaAsP), aluminum indium arsenide (AlInAs), aluminum gallium arsenide (AlGaAs), gallium indium arsenide (GaInAs), gallium indium phosphide (GaInP), and/or gallium indium arsenic phosphide (GaInAsP); other group III-V materials; other group II-V materials; or combinations thereof. In some embodiments, the substrate 42 may be a glass substrate or any other substrate material.

A semiconductor device 44 is provided in the substrate 42, in accordance with some embodiments. In some embodiments, the semiconductor device 44 may include elements of a processor, such as a system-on-chip (SoC), a central processing unit (CPU), a graphics processing unit (GPU), or the like. In some embodiments, the semiconductor device 44 may include elements of a memory die such as a DRAM, high bandwidth memory (HBM), memory cube, a memory stack, or the like. In some embodiments, the semiconductor device 44 may include elements of semiconductor stacked dies such as memory, flash, converter, sensor, logic die, and the like. A conductive feature 46 is formed over the semiconductor device 44 and electrically connected to the semiconductor device 44. In some embodiments, materials of the conductive feature 46 may include Tungsten (W), aluminum (Al), copper (Cu), titanium (Ti), tantalum (Ta), titanium nitride (TiN), tantalum nitride (TaN), alloys or multiple layers thereof, or the like. A passivation layer 48 is disposed over the substrate 42, the semiconductor device 44, and the conductive feature 46. The passivation layer 48 may comprise polymers such as PBO, polyimide, BCB, or the like. Alternatively, the passivation layer 48 may include non-organic dielectric materials such as silicon oxide, silicon nitride, silicon carbide, silicon oxynitride, or the like. The passivation layer 48 may be deposited by, for example, CVD, PVD, ALD, or the like.

In FIG. 2B, a dielectric structure 50 may be formed over the conductive feature 46 and the passivation layer 48. In some embodiments, the dielectric structure 50 may be made of a polymer material such as epoxy, polyimide, polybenzoxazole (PBO), benzocyclobutene (BCB), solder resist (SR), ABF film, and the like, in accordance with some embodiments. In some embodiments, the dielectric structure 50 is made of a photosensitive material and may undergo chemical reactions when exposed to light. In some embodiments, the dielectric structure 50 may include phospho-silicate glass (PSG), boro-silicate glass (BSG), boron-doped phospho-silicate glass (BPSG), undoped silicate glass (USG), or the like. In some embodiments of the present disclosure, the dielectric structure 50 may include an inorganic dielectric material, which may include a material selected from silicon nitride (SiNₓ), silicon oxide (SiO₂), silicon oxy-nitride (SiONₓ), silicon oxy-carbide (SiOCₓ), silicon carbide (SiC), combinations or multiple layers thereof, or the like.

In some embodiments, the material of the dielectric structure 50 is different from the material of the dielectric layers 12, 16, and 20. For example, in some embodiments, the dielectric structure 50 may have a coefficient of thermal expansion (CTE) of greater than 30 ppm/° C. below its glass transition temperature (Tg), which is less than about 280° C. In some embodiments, the dielectric structure 50 has a Young's modulus less than about 4 GPa. In some embodiments, the dielectric structure 50 has a dielectric constant (dk) greater than about 3 F/m. In some embodiments, the dielectric structure 50 has a dissipation factor (df) greater than about 0.005. In some embodiments, the dielectric structure 50 may have a coefficient of thermal expansion (CTE) of greater than 30 ppm/° C. below its glass transition temperature (Tg), which is less than about 280° C. In some embodiments, the Young's modulus of the dielectric structure 50 is less than the Young's modulus of the dielectric layers 12, 16, and 20. In some embodiments, the dielectric constant (dk) of the dielectric structure 50 is greater than the dielectric constant (dk) of the dielectric layers 12, 16, and 20. In some embodiments, the dissipation factor (df) of the dielectric structure 50 is greater than the dissipation factor (df) of the dielectric layers 12, 16, and 20.

As shown in FIG. 2C, openings 52 are formed in the dielectric structure 50 to expose the conductive feature 46 from the openings 52. For example, a patterned mask (e.g., photoresist or a combination of photoresist and hard mask) may be formed over the dielectric structure 50, and an etching process such as a dry etching process and/or a wet etching process may be performed to form the openings 52 according to the pattern of the patterned mask.

As shown in FIG. 2D, a conductive layer 54 is formed over the dielectric structure 50 and in the opening 52. The conductive layer 54 may be a seed layer, and may include a titanium layer and a copper layer over the titanium layer. In some embodiments, the conductive layer 54 includes a copper layer in contact with the passivation layer 48, the dielectric structure 50, and the conductive feature 46. The conductive layer 54 may be formed by a deposition process such as PVD, or the like.

As shown in FIG. 2E, a photoresist layer 56 is formed over the conductive layer 54. The photoresist layer 56 may be formed by depositing a photosensitive layer over the conductive layer 54 using spin-on coating or the like.

In FIG. 2F, the photoresist layer 56 may then be patterned by exposing the photoresist layer 56 to a patterned energy source (e.g., a patterned light source) and developing the photoresist layer 56 to remove an exposed or unexposed portion of the photoresist layer 56. The openings 57, which expose the conductive layer 54, are then formed extending through the photoresist layer 56.

In some embodiments, as shown in FIG. 2G, a conductive layer is formed over the photoresist layer 56 and in the openings 57. For example, a liner layer, which may include a barrier layer, an adhesion layer, and/or a seed layer, may be formed in the openings 57 by a deposition method, such as chemical vapor deposition (CVD), physical vapor deposition (PVD), or atomic layer deposition (ALD). The liner may include Tungsten (W), aluminum (Al), copper (Cu), titanium (Ti), tantalum (Ta), titanium nitride (TiN), tantalum nitride (TaN), alloys or multiple layers thereof, or the like. In some embodiments, a low-resistance conductive material is formed over the liner and fills the remaining portions of the openings 57 in the photoresist layer 56. For example, the low-resistance conductive material may be formed by electroplating, electroless plating, CVD, PVD, a combination thereof, or the like. Afterwards, excess materials of the liner layer and the low-resistance conductive material over the photoresist layer 56 may be removed by a planarization process, such as chemical mechanical polishing (CMP) or a mechanical grinding process. The liner layer and the low-resistance conductive material in the openings 57 of the photoresist layer 56 may form the conductive features 58. In some embodiments, the conductive features 58 may include metal vias and metal lines. In some embodiments, the photoresist layer 56 and the conductive features 58 may have a coplanar top surface for providing a flat platform for overlying layers being formed over the photoresist layer 56 and the conductive features 58.

In FIG. 2H, the photoresist layer 56 and portions of the conductive layer 54 on which the conductive feature 58 is not formed are removed. The photoresist layer 56 may be removed by an acceptable ashing or stripping process, such as using an oxygen plasma or the like. Once the photoresist layer 56 is removed, exposed portions of the conductive layer 54 are removed using an acceptable etching process, such as wet or dry etching. One or more optional cleaning processes may also be performed. Afterwards, a planarization process, such as chemical mechanical polishing (CMP) or a mechanical grinding process, is performed to level the top surfaces of the dielectric structure 50 and the conductive features 58. The remained conductive layer 54 and the conductive features 58 may be collectively called as conductive elements 60. In some embodiments of the present disclosure, the conductive elements 60 may include metal vias, metal lines, and/or metal pads.

In FIG. 2I, the redistributing structure 28 is aligned with the underneath structure. For example, in some embodiment, the alignment mark 23 exposed from the top surface 25 of the redistributing structure 28 allows the vertical and/or horizontal positions of the redistributing structure 28 relative to the underneath structure to be measured. For example, the conductive feature 14 is aligned with the conductive element 60, which means they overlap each other in the vertical direction.

In FIG. 2J, a bottom surface 37 of the redistributing structure 28 is bonded to the top surface 50t of the dielectric structure 50 to form a semiconductor chip 62. In some embodiments, the redistributing structure 28 is bonded to the underneath structure by hybrid bonding. For example, the dielectric layer 12 is bonded to the dielectric structure 50 by dielectric-to-dielectric bonding, and the conductive feature 14 is bonded to the conductive element 60 by metal-to-metal bonding. The redistributing structure 28 is thus in contact with the dielectric structure 50 and the conductive element 60. In some embodiments, grain size of the materials of the conductive features 14 and the conductive element 60 increase and growth, so no obviously interface is shown between the conductive features 14 and the conductive element 60.

In some embodiments, the material composition nearby the interface between the conductive features 14 and the conductive element 60 is different from the other positions of the conductive features 14 and the conductive element 60. For example, the material composition nearby the interface has 10 atomic % lower carbon atoms, which includes 5 atomic % lower C—C and C—N bonds, and 5 atomic % higher C—O and C═O bonds. More C—OH bond is also observed. The material composition nearby the interface also has 5 atomic % lower C—N—C bond, 5 atomic % higher H—N—C bond, and 5 atomic % lower C—N bond. The material composition nearby the interface has 10 atomic % higher oxygen atoms, which includes 5 atomic % lower O═C bond and 5 atomic % higher C—O bond. In some embodiments, the atomic composition may be inspected by Energy-dispersive X-ray spectroscopy (EDS) or Fourier-transform infrared spectroscopy (FTIR).

The semiconductor chip 62 may be a single die or die stacks. In some embodiments, the semiconductor chip 62 may be a processor, such as a system-on-chip (SoC), a central processing unit (CPU), a graphics processing unit (GPU), or the like. In some embodiments, the semiconductor chip 62 may be a memory die such as a DRAM, high bandwidth memory (HBM), memory cube, a memory stack, or the like. In some embodiments, the semiconductor chip 62 may include semiconductor stacked dies such as memory, flash, converter, sensor, logic die, and the like.

In some embodiments, an interface 35 is formed between the dielectric structure 50 and the conductive element 60 and the sublayer 30. The interface 35 has a peak-to-valley (PV) flatness between about 5 nm and about 100 nm, such as between about 10 nm and about 50 nm. This is because the dielectric structure 50 and the conductive element 60 is planarized by a chemical mechanical polishing (CMP) process or a mechanical grinding process, leading to a lower peak-to-valley flatness. Therefore, problems occurred during thermal process such as warpage and residue stress may be mitigated.

In FIG. 2K, conductive features 36 and 38 are formed on the semiconductor chip 62, in accordance with some embodiments. The conductive features 36 may be formed over the conductive features 24, and then the conductive features 38 may be formed over the conductive features 36. In some embodiments, the conductive features 36 include metal pillars. In some embodiments, the conductive features 36 include tungsten (W), aluminum (Al), copper (Cu), titanium (Ti), tantalum (Ta), titanium nitride (TiN), tantalum nitride (TaN), alloys or multiple layers thereof, or the like. In some embodiments, the conductive features 38 include a solder material, such as Sn and Ag or another suitable conductive material (e.g., gold), in accordance with some embodiments of the present disclosure. The conductive features 38 may include conductive pillars, solder balls, controlled collapse chip connection (C4) bumps, micro bumps, one or more other suitable bonding structures, or a combination thereof.

FIG. 3A to FIG. 3I are schematic views of a process for forming a semiconductor package structure 100, in accordance with some embodiments. In FIG. 3A, a release film 71 is formed over a substrate 70, and then an interposer 72 is formed over the release film 71. The interposer 72 includes a dielectric material 74, conductive features 76 formed in the dielectric material 74, and conductive features 78 formed over the dielectric material 74.

In some embodiments, the substrate 70 may be made of silicon (Si) or other semiconductor materials, such as germanium (Ge) or silicon germanium (SiGe). In some embodiments, the substrate 70 may include a compound semiconductor, such as silicon carbide (SiC), silicon phosphide (SiP), gallium arsenide (GaAs), gallium phosphide (GaP), indium phosphide (InP), indium arsenide (InAs), indium antimonide (InSb), zinc oxide (ZnO), zinc selenide (ZnSe), zinc sulfide (ZnS), zinc telluride (ZnTe), cadmium selenide (CdSe), cadmium sulfide (CdS), and/or cadmium telluride (CdTe); an alloy semiconductor, such as silicon germanium (SiGe), silicon phosphorus carbide (SiPC), gallium arsenic phosphide (GaAsP), aluminum indium arsenide (AlInAs), aluminum gallium arsenide (AlGaAs), gallium indium arsenide (GaInAs), gallium indium phosphide (GaInP), and/or gallium indium arsenic phosphide (GaInAsP); other group III-V materials; other group II-V materials; or combinations thereof. In some embodiments, the substrate 70 may be a glass substrate or any other substrate material.

In some embodiments, the release film 71 may be formed of a polymer-based material and/or an epoxy-based thermal-release material (such as a Light-To-Heat-Conversion (LTHC) material), which is capable of being decomposed under radiation such as a laser beam, so that the substrate 70 may be de-bonded from the overlying structures that will be formed in subsequent processes. In accordance with some embodiments of the present disclosure, the release film 71 is applied on the substrate 70 through coating.

In some embodiments, the dielectric material 74 may be made of a polymer material such as epoxy, polyimide, polybenzoxazole (PBO), benzocyclobutene (BCB), solder resist (SR), ABF film, and the like, in accordance with some embodiments. In some embodiments, the dielectric material 74 is made of a photosensitive material and may undergo chemical reactions when exposed to light.

In some embodiments, the conductive features 76 and 78 may be formed by a deposition method, such as chemical vapor deposition (CVD), physical vapor deposition (PVD), atomic layer deposition (ALD), or by electroplating, electroless plating, a combination thereof, or the like. In some embodiments, the materials of the conductive features 76 and 78 may include Tungsten (W), aluminum (Al), copper (Cu), titanium (Ti), tantalum (Ta), titanium nitride (TiN), tantalum nitride (TaN), alloys or multiple layers thereof, or the like.

As shown in FIG. 3B, the semiconductor chips 62 are bonded to the interposer 72. In some embodiments, the conductive features 36 are bonded to the conductive features 78 through the conductive features 38. A reflow process may be performed to make the metallurgical connections between the semiconductor chips 62, the conductive features 36, 38, and 78, and the interposer 72, in accordance with some embodiments of the present disclosure.

As shown in FIG. 3C, an underfill material 80 is dispensed (e.g., by a dispenser (not shown)) into the space between each semiconductor chip 62 and the interposer 72 and the space between adjacent conductive features 36, 38, and 78, and then cured (e.g., ultraviolet (UV) or thermally cured) to harden. The underfill material 80 may be configured to provide a stronger mechanical connection and a heat bridge between the semiconductor chip 62 and the interposer 72, to reduce cracking in the conductive features 36, 38, and 78 caused by thermal expansion mismatches between the semiconductor chip 62 and the interposer 72, and to protect the joints from contaminants, thereby improving reliability of the fabricated semiconductor package structure 100 (FIG. 3J), in accordance with some embodiments of the present disclosure. In some embodiments, the underfill material 80 includes liquid epoxy, deformable gel, silicon rubber, or the like.

In FIG. 3D, a molding layer 82 is formed over the semiconductor chips 62, the underfill material 80, and the interposer 72 to encapsulate the elements, in accordance with some embodiments. The molding layer 82 fills gaps between the semiconductor chips 62, in accordance with some embodiments. The molding layer 82 in the gaps surrounds the semiconductor chips 62, in accordance with some embodiments. The molding layer 82 may be configured to provide package stiffness, a protective or hermetic shielding, and/or provide a heat conductive path to prevent chip overheating, in accordance with some embodiments of the present disclosure. The molding layer 82 may be formed by a spin-on coating process, an injection molding process, or the like, in accordance with some embodiments of the present disclosure.

The molding layer 82 includes a polymer material, in accordance with some embodiments. The term “polymer” here can represent thermosetting polymers, thermoplastic polymers, or any mixtures thereof, in accordance with some embodiments. The polymer material can include, for example, plastic materials, epoxy resin, polyimide, polyethylene terephthalate (PET), polyvinyl chloride (PVC), polymethylmethacrylate (PMMA), polymer components doped with specific fillers including fiber, clay, ceramic, inorganic particles, or any combinations thereof. In other embodiments, the molding layer 82 can be made of epoxy resin, such as epoxy cresol novolac (ECN), biphenyl epoxy resin, multifunctional liquid epoxy resin, or any combinations thereof, in accordance with some embodiments. In still other embodiments, the molding layer 82 can be made of epoxy resin optionally including one or more fillers to provide the composition with any of a variety of desirable properties. Examples of fillers can be aluminum, titanium dioxide, carbon black, calcium carbonate, silica, or any combinations thereof, in accordance with some embodiments. A thermal process is performed on the molding layer 82 to cure the molding layer 82, in accordance with some embodiments of the present disclosure.

Afterwards, an upper portion of the molding layer 82 is removed to expose top surfaces of the semiconductor chips 62, in accordance with some embodiments. After the removal process, a top surface of the molding layer 82 is substantially coplanar with or aligned with the top surfaces of the semiconductor chips 62, in accordance with some embodiments. The removal process includes a chemical mechanical polishing (CMP) process or another suitable grinding or etching process, in accordance with some embodiments.

As shown in FIG. 3E, the substrate 70 is then de-bonded from the interposer 72, for example, by projecting UV light or a laser beam, which penetrates through the substrate 70, on the release film 71. The release film 71 decomposes under the heat of the UV light or the laser beam. The remained interposer 72 may then be de-bonded from the substrate 70. Afterwards, the entire structure is flipped upside down and disposed on a substrate 84 having a release film 81 disposed on the substrate 84. The top surfaces of the semiconductor chips 62 and the molding layer 82 are in contact with the release film 81.

In some embodiments, the substrate 84 may be made of silicon (Si) or other semiconductor materials, such as germanium (Ge) or silicon germanium (SiGe). In some embodiments, the substrate 84 may include a compound semiconductor, such as silicon carbide (SiC), silicon phosphide (SiP), gallium arsenide (GaAs), gallium phosphide (GaP), indium phosphide (InP), indium arsenide (InAs), indium antimonide (InSb), zinc oxide (ZnO), zinc selenide (ZnSe), zinc sulfide (ZnS), zinc telluride (ZnTe), cadmium selenide (CdSe), cadmium sulfide (CdS), and/or cadmium telluride (CdTe); an alloy semiconductor, such as silicon germanium (SiGe), silicon phosphorus carbide (SiPC), gallium arsenic phosphide (GaAsP), aluminum indium arsenide (AlInAs), aluminum gallium arsenide (AlGaAs), gallium indium arsenide (GaInAs), gallium indium phosphide (GaInP), and/or gallium indium arsenic phosphide (GaInAsP); other group III-V materials; other group II-V materials; or combinations thereof. In some embodiments, the substrate 84 may be a glass substrate or any other substrate material.

In some embodiments, the release film 81 may be formed of a polymer-based material and/or an epoxy-based thermal-release material (such as a Light-To-Heat-Conversion (LTHC) material), which is capable of being decomposed under radiation such as a laser beam, so that the substrate 84 may be de-bonded from the overlying structures that will be formed in subsequent processes. In accordance with some embodiments of the present disclosure, the release film 81 is applied on the substrate 84 through coating.

In FIG. 3F, conductive features 86 are formed on a bottom surface 72b of the interposer 72 and in contact with the conductive features 76 exposed from the bottom surface 72b. The conductive features 86 may include conductive pillars, solder balls, controlled collapse chip connection (C4) bumps, micro bumps, one or more other suitable bonding structures, or a combination thereof.

In FIG. 3G, the interposer 72 is disposed on a substrate 88 through the conductive features 86 disposed on the interposer 72 and the conductive features 90 disposed on the substrate 88, in accordance with some embodiments. In some embodiments, the substrate 88 is a semiconductor substrate. By way of example, the material of the substrate 88 may include elementary semiconductor such as silicon or germanium; a compound semiconductor such as silicon germanium, silicon carbide, gallium arsenic, gallium phosphide, indium phosphide or indium arsenide; or combinations thereof. Alternatively, the substrate 88 may be a silicon-on-insulator (SOI) substrate, a germanium-on-insulator (GOI) substrate, or the like. In some other embodiments, the substrate 88 is a printed circuit board (PCB), a ceramic substrate, or another suitable package substrate. The substrate 88 may be a core or a core-less substrate, in accordance with some embodiments.

As shown in FIG. 3H, a reflow process (not shown) may be performed to make the metallurgical connections between the substrate 88, the conductive features 86 and 90 (collectively called as conductive features 92 after the reflow process), and the interposer 72, in accordance with some embodiments of the present disclosure. In some embodiments, the second intermediate substrate is removed after the interposer 72 is disposed on the substrate 88. The substrate 84 is then de-bonded from the semiconductor chips 62 and the molding layer 82, for example, by projecting UV light or a laser beam, which penetrates through the substrate 84, on the release film 81. The release film 81 decomposes under the heat of the UV light or the laser beam. The remained semiconductor chips 62 and the molding layer 82 may then be de-bonded from the substrate 84.

In some embodiments of the present disclosure, the substrate 88 has various device elements (not shown). Examples of device elements that are formed in or on the substrate 88 may include transistors (e.g., metal oxide semiconductor field effect transistors (MOSFET), complementary metal oxide semiconductor (CMOS) transistors, bipolar junction transistors (BJT), high voltage transistors, high-frequency transistors, p-passage and/or n-passage field-effect transistors (PFETs/NFETs), etc.), diodes, resistors, capacitors, inductors, and/or other applicable device elements. Various processes can be performed to form the device elements, such as deposition, etching, implantation, photolithography, annealing, and/or other suitable processes. In some embodiments of the present disclosure, the substrate 88 may also have one or more circuit layers (not shown) used to electrically connect the device elements and semiconductor devices that are subsequently attached.

The substrate 88 generally has a rectangular (or square) shape in a top view, depending on design requirements, although other shapes may also be used. Also, the substrate 88 has opposite surfaces, which may be substantially parallel to each other. The upper surface may be used to receive and bond other package components of the package.

In FIG. 3I, an underfill material 94 is dispensed (e.g., by a dispenser (not shown)) into the space between the interposer 72 and the substrate 88 and the space between adjacent conductive features 92, and then cured (e.g., ultraviolet (UV) or thermally cured) to harden. The underfill material 94 may be configured to provide a stronger mechanical connection and a heat bridge between the interposer 72 and the substrate 88, to reduce cracking in the conductive features 92 caused by thermal expansion mismatches between the interposer 72 and the substrate 88, and to protect the joints from contaminants, thereby improving reliability of the fabricated semiconductor package structure 100, in accordance with some embodiments of the present disclosure. In some embodiments, the underfill material 94 includes liquid epoxy, deformable gel, silicon rubber, or the like.

In some embodiments, conductive features 96 may be provided on a bottom surface 88b of the substrate 88 to enable electrical connection between the substrate 88 and an external electronic device such as a PCB (not shown). The conductive features 96 may be or include solder balls such as tin-containing solder balls, in accordance with some embodiments of the present disclosure. Therefore, the semiconductor package structure 100 is formed.

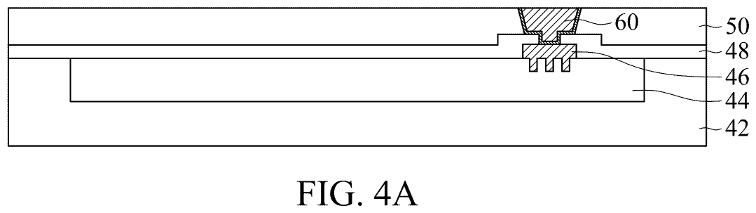

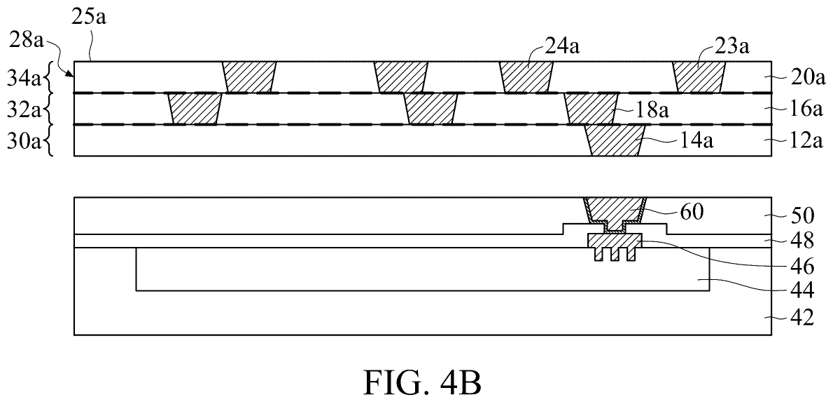

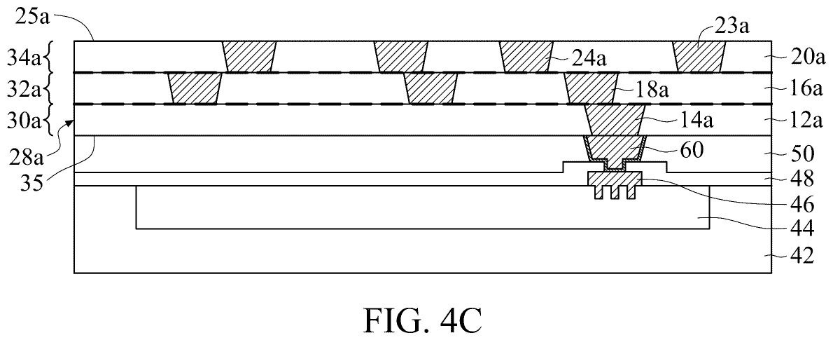

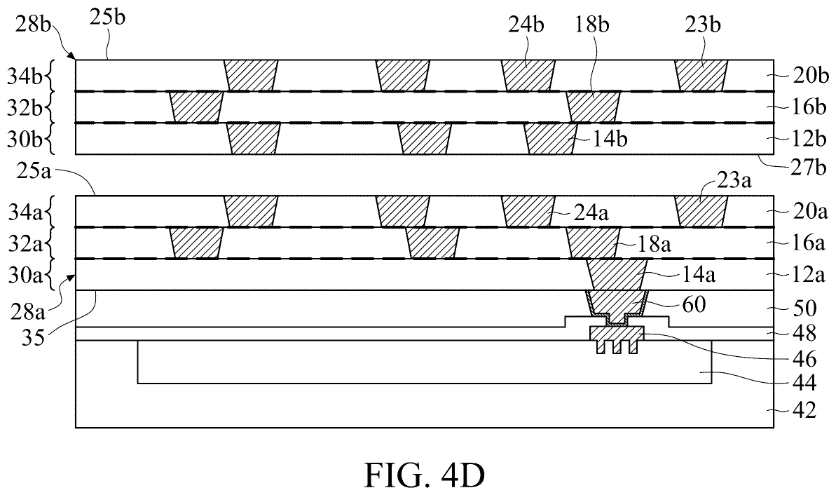

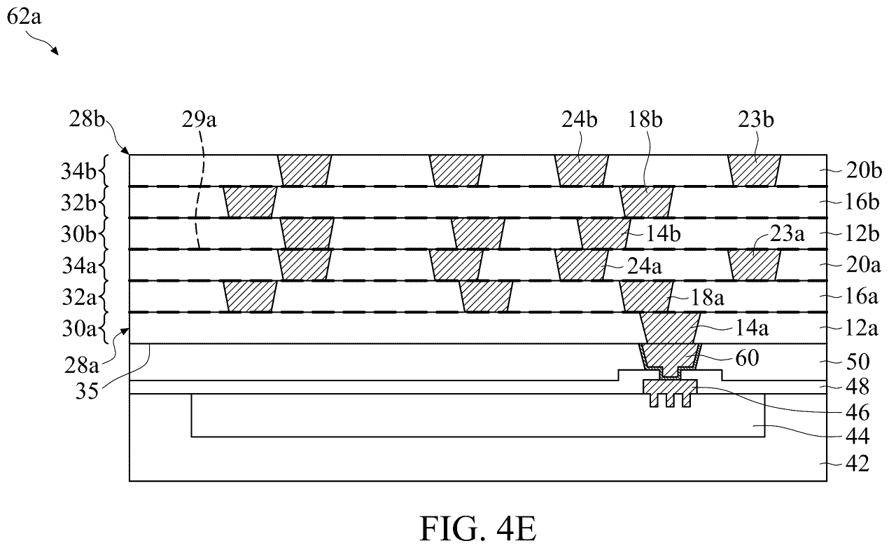

FIG. 4A to FIG. 4E are schematic views of a process for forming a semiconductor chip 62a, in accordance with some embodiments. In some embodiments, the same structure shown in FIG. 2H is provided in FIG. 4A, and the details are not described again for simplicity. In FIG. 4B, a redistributing structure 28a is aligned with the underneath structure. The redistributing structure 28a may have a similar structure to the redistributing structure 28 shown in FIG. 1P, such as may have sublayers 30a, 32a, and 34a, which include dielectric layers 12a, 16a, and 20a, and conductive features 14a, 18a, and 24a, respectively. The detail is not described again for simplicity.

In some embodiments, the redistributing structure 28a is aligned with the underneath structure through the alignment mark 23a exposed from a top surface 25a of the redistributing structure 28a. The top surface 25a faces away from the underneath structure (such as the substrate 42 and the dielectric structure 50). The exposed alignment mark 23a allows the position of the redistributing structure 28a being determined by optical method, such as may be detected by light (e.g. laser, visible, infrared, or ultraviolet). As a result, the redistributing structure 28a may be aligned with the underneath structure. In some embodiments, the alignment mark 23a is electrically isolated from the conductive features 14a, 18a, and 24a in the redistributing structure 28a.

As shown in FIG. 4C, the redistributing structure 28a is bonded to the underneath structure. In particular, the dielectric layer 12a is bonded to the dielectric structure 50 by dielectric-to-dielectric bonding, and the conductive feature 14a is bonded to the conductive element 60 by metal-to-metal bonding. Suitable heating and pressing processes are performed at this stage in some embodiments.

In FIG. 4D, a redistributing structure 28b is aligned with the underneath structure (the redistributing structure 28a). The redistributing structure 28b may have a similar structure to the redistributing structure 28 shown in FIG. 1P, such as may have sublayers 30b, 32b, and 34b, which include dielectric layers 12b, 16b, and 20b, and conductive features 14b, 18b, and 24b, respectively. The detail is not described again for simplicity.

In some embodiments, the redistributing structure 28b is aligned with the redistributing structure 28a through the alignment mark 23b exposed from a top surface 25b of the redistributing structure 28a. In some embodiments, the alignment mark 23b is electrically isolated from the conductive features 14b, 18b, and 24b in the redistributing structure 28b.

As shown in FIG. 4E, the redistributing structure 28b is bonded to the redistributing structure 28a by bonding the top surface 25a to the bottom surface 27b to form an interface 29a. In particular, the dielectric layer 12b is bonded to the dielectric layer 12a by dielectric-to-dielectric bonding, and the conductive feature 14b is bonded to the conductive feature 24a by metal-to-metal bonding. Suitable heating and pressing processes are performed at this stage in some embodiments. The alignment mark 23a is covered by the redistributing structure 28b. Therefore, the semiconductor chip 62a is formed.

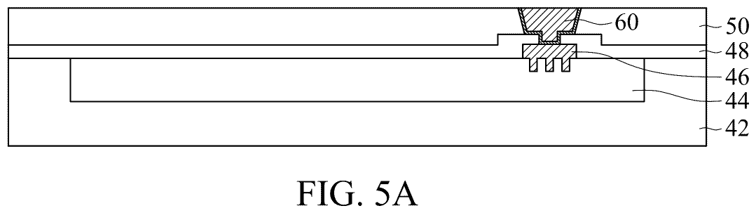

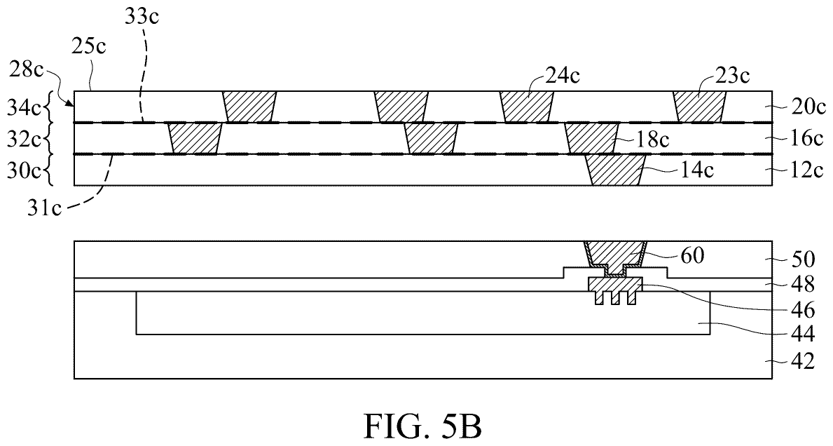

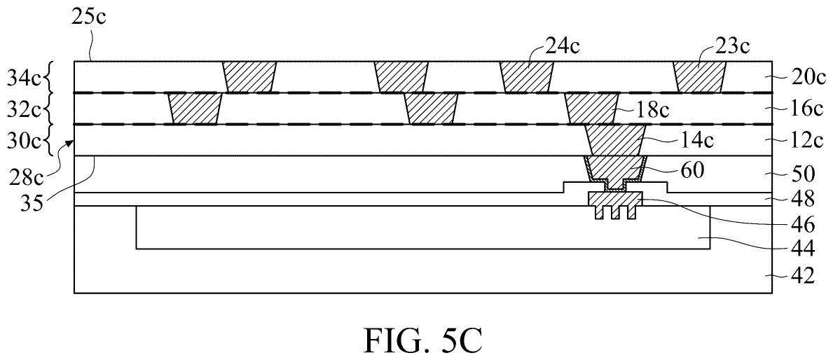

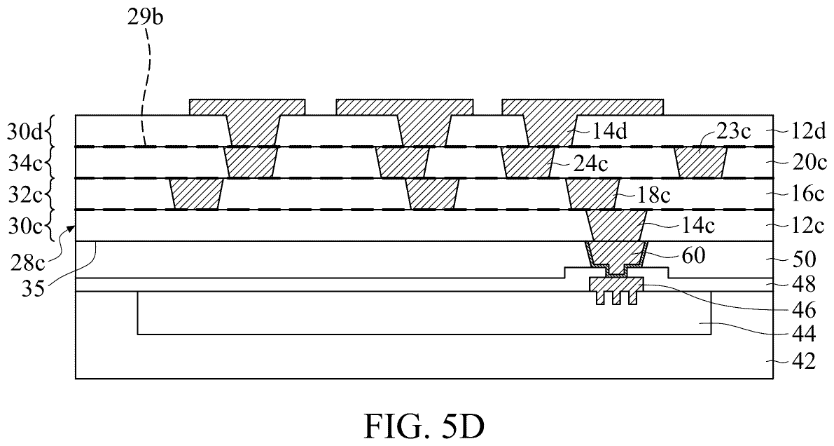

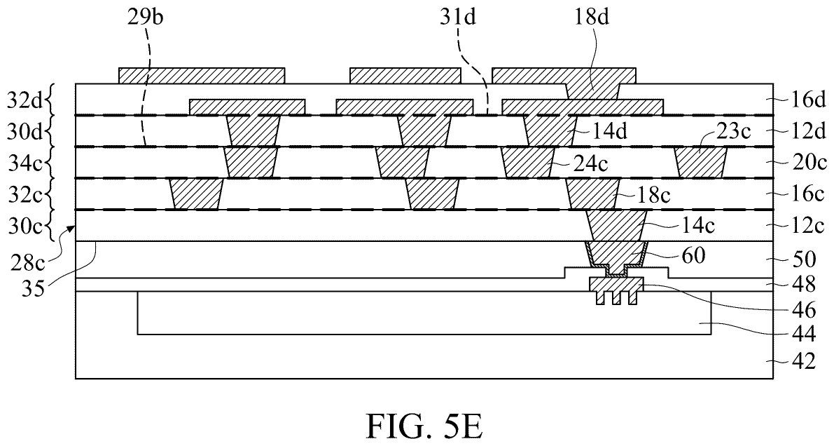

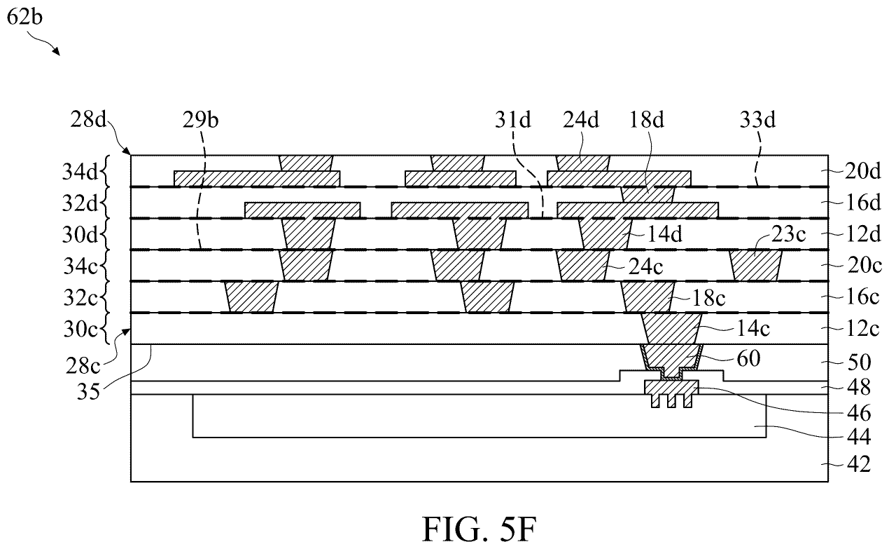

FIG. 5A to FIG. 5F are schematic views of a process for forming a semiconductor chip 62b, in accordance with some embodiments. In some embodiments, the same structure shown in FIG. 2H is provided in FIG. 5A, and the details are not described again for simplicity. In FIG. 5B, a redistributing structure 28c is aligned with the underneath structure. The redistributing structure 28c may have a similar structure to the redistributing structure 28 shown in FIG. 1P, such as may have sublayers 30c, 32c, and 34c, which include dielectric layers 12c, 16c, and 20c, and conductive features 14c, 18c, and 24c, respectively. An interface 31c is between the sublayers 30c and 32c, and an interface 33c is between the sublayers 32c and 34c. The detail is not described again for simplicity.

In some embodiments, the redistributing structure 28c is aligned with the underneath structure through the alignment mark 23c exposed from a top surface 25c of the redistributing structure 28c. The top surface 25c faces away from the underneath structure (such as the substrate 42 and the dielectric structure 50). The exposed alignment mark 23c allows the position of the redistributing structure 28c being determined by optical method, such as may be detected by light (e.g. laser, visible, infrared, or ultraviolet). As a result, the redistributing structure 28c may be aligned with the underneath structure. In some embodiments, the alignment mark 23c is electrically isolated from the conductive features 14c, 18c, and 24c in the redistributing structure 28c.

As shown in FIG. 5C, the redistributing structure 28c is bonded to the underneath structure. In particular, the dielectric layer 12c is bonded to the dielectric structure 50 by dielectric-to-dielectric bonding, and the conductive feature 14c is bonded to the conductive element 60 by metal-to-metal bonding. Suitable heating and pressing processes are performed at this stage in some embodiments.

In FIG. 5D, a sublayer 30d is formed over the sublayer 34c. The sublayer 30d includes a dielectric layer 12d and conductive features 14d formed in the dielectric layer 12d. Some of the conductive features 14d are formed over the dielectric layer 12d. An interface 29b is between the sublayers 30d and 34c. In FIG. 5E, a sublayer 32d is formed over the sublayer 30d. The sublayer 32d includes a dielectric layer 16d and conductive features 18d formed in the dielectric layer 16d. Some of the conductive features 18d are formed over the dielectric layer 16d. An interface 31b is between the sublayers 30d and 32d. In FIG. 5F, a sublayer 34d is formed over the sublayer 32d. The sublayer 32d includes a dielectric layer 20d and conductive features 24d formed in the dielectric layer 20d. Some of the conductive features 24d are formed over the dielectric layer 20d. An interface 33d is between the sublayers 32d and 34d.

In some embodiments, the peak-to-valley flatness of the interface 29b is different from the peak-to-valley flatness of the interface 31d and 33d. For example, the peak-to-valley flatness of the interface 29b may be between about 5 nm and about 100 nm, such as between about 10 nm and about 50 nm. The peak-to-valley flatness of the interface 31d and 33d may be between about 1 um and about 20 um. This is because the top surface 25c of the redistributing structure 28c is planarized by a chemical mechanical polishing (CMP) process or a mechanical grinding process, leading to a lower peak-to-valley flatness. Therefore, problems occurred during thermal process such as warpage and residue stress may be mitigated. Therefore, the semiconductor chip 62b is formed.

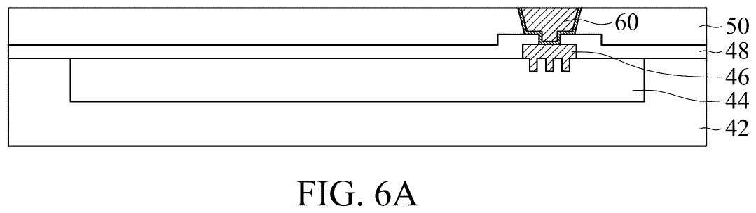

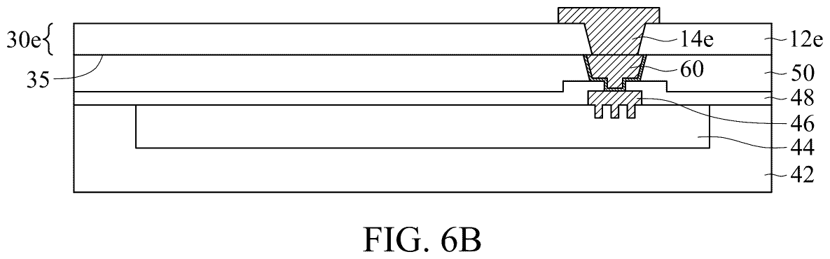

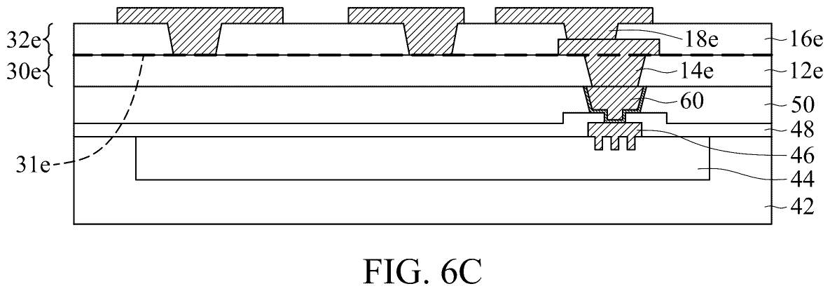

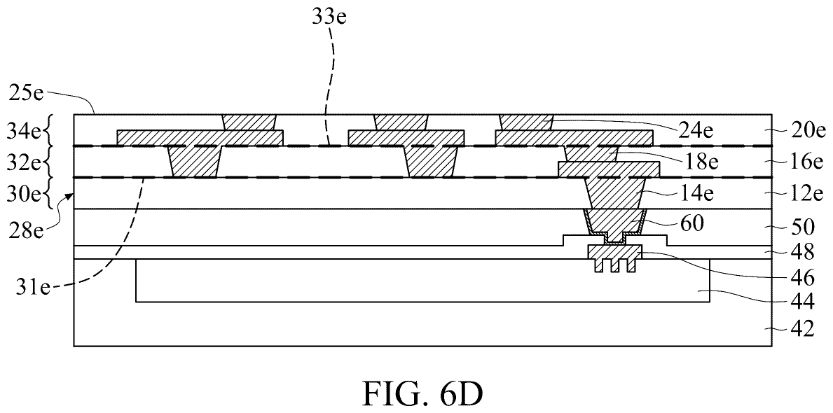

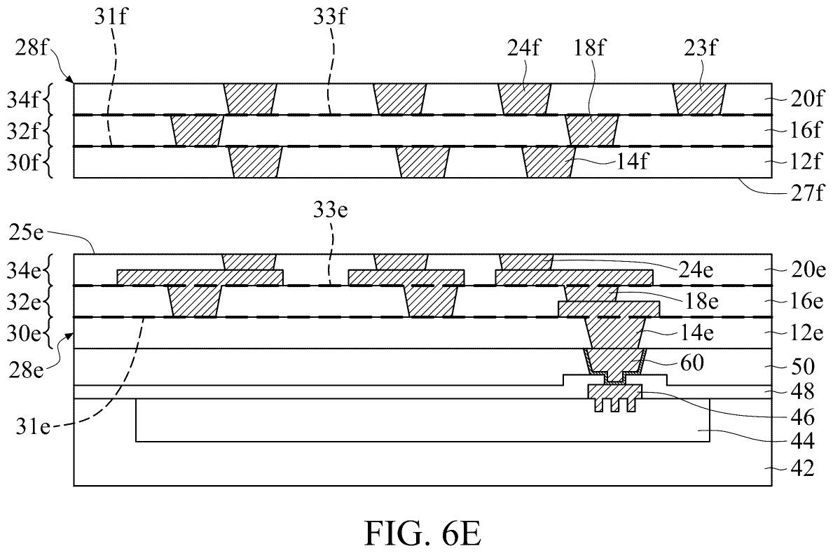

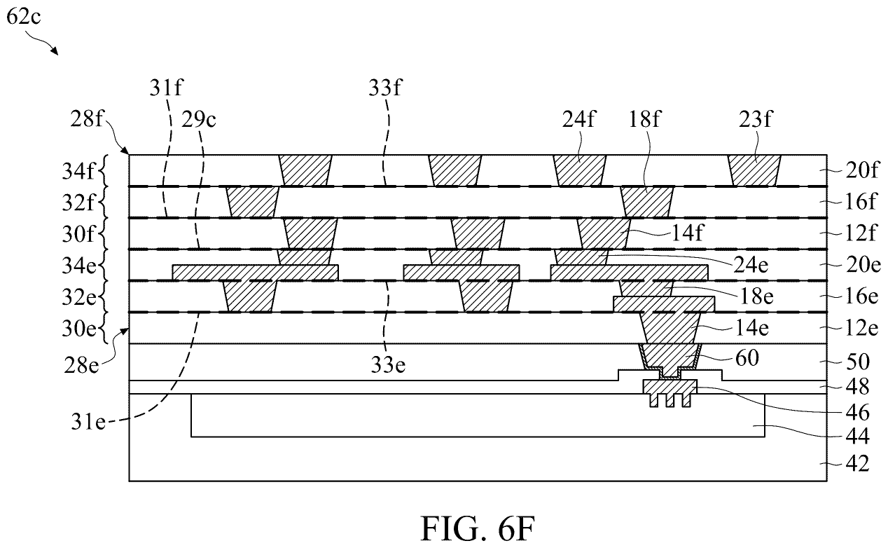

FIG. 6A to FIG. 6E are schematic views of a process for forming a semiconductor chip 62c, in accordance with some embodiments. In some embodiments, the same structure shown in FIG. 2H is provided in FIG. 6A, and the details are not described again for simplicity. In FIG. 6B, a sublayer 30e is formed over the dielectric structure 50, and an interface 35 is between the sublayer 30e and the dielectric structure 50. The sublayer 30e includes a dielectric layer 12e and conductive features 14e formed in the dielectric layer 12e. Some of the conductive features 14e are formed over the dielectric layer 12e. In FIG. 6C, a sublayer 32e is formed over the sublayer 30e. The sublayer 32e includes a dielectric layer 16e and conductive features 18e formed in the dielectric layer 16e. Some of the conductive features 18e are formed over the dielectric layer 16e. An interface 31e is between the sublayers 30e and 32e. In FIG. 6D, a sublayer 34e is formed over the sublayer 32e. The sublayer 32e includes a dielectric layer 20e and conductive features 24e formed in the dielectric layer 20e. Some of the conductive features 24e are formed over the dielectric layer 20e. An interface 33e is between the sublayers 32e and 34e. The sublayers 30e, 32e, and 34e are collectively called as a redistributing structure 28e.

As shown in FIG. 6E, a redistributing structure 28f is aligned with the redistributing structure 28e. The redistributing structure 28f may have a similar structure to the redistributing structure 28 shown in FIG. 1P, such as may have sublayers 30f, 32f, and 34f, which include dielectric layers 12f, 16f, and 20f, and conductive features 14f, 18f, and 24f, respectively. An interface 31f is between the sublayers 30f and 32f, and an interface 33f is between the sublayers 32f and 34f. The detail is not described again for simplicity.

In some embodiments, the redistributing structure 28f is aligned with the redistributing structure 28e through the alignment mark 23f exposed from a top surface 25f of the redistributing structure 28f. The top surface 25f faces away from the redistributing structure 28e. The exposed alignment mark 23f allows the position of the redistributing structure 28f being determined by optical method, such as may be detected by light (e.g. laser, visible, infrared, or ultraviolet). As a result, the redistributing structure 28f may be aligned with the redistributing structure 28e. In some embodiments, the alignment mark 23f is electrically isolated from the conductive features 14f, 18f, and 24f in the redistributing structure 28f.

As shown in FIG. 6F, the redistributing structure 28f is bonded to the redistributing structure 28e. An interface 29c is formed by a top surface 25e of the redistributing structure 28e and a bottom surface 27f of the redistributing structure 28f. In particular, the dielectric layer 12f is bonded to the dielectric layer 20e by dielectric-to-dielectric bonding, and the conductive feature 14f is bonded to the conductive feature 24e by metal-to-metal bonding. Suitable heating and pressing processes are performed at this stage in some embodiments.

In some embodiments, the peak-to-valley flatness of the interface 35 is different from the peak-to-valley flatness of the interfaces 29c, 31d and 33d. For example, the peak-to-valley flatness of the interface 35 may be between about 5 nm and about 100 nm, such as between about 10 nm and about 50 nm. The peak-to-valley flatness of the interfaces 29c, 31d and 33d may be between about 1 um and about 20 um. This is because the dielectric structure 50 and the conductive element 60 are planarized by a chemical mechanical polishing (CMP) process or a mechanical grinding process, leading to a lower peak-to-valley flatness. Therefore, problems occurred during thermal process such as warpage and residue stress may be mitigated. Moreover, the peak-to-valley flatness of the interfaces 31f and 33f are also less than the peak-to-valley flatness of the interfaces 29c, 31d and 33d. For example, the peak-to-valley flatness of the interfaces 31f and 33f may be between about 5 nm and about 100 nm, such as between about 10 nm and about 50 nm. This is because the sublayers 30f and 32f are planarized by a chemical mechanical polishing (CMP) process or a mechanical grinding process, leading to a lower peak-to-valley flatness. Therefore, problems occurred during thermal process such as warpage and residue stress may be mitigated. Therefore, the semiconductor chip 62c is formed.

In summary, a semiconductor structure and a method for forming the same are provided. Such structure and method reduce the peak-to-valley flatness between the sublayers of the redistributing structure to mitigate warpage of the entire structure. Such process also reduces the number of thermal process cycle, which also prevents warpage from occurring.

A method for forming a semiconductor structure is provided in some embodiments of the present disclosure. The method includes forming a first redistributing structure over a first carrier, detaching the first redistributing structure from the first carrier, forming a dielectric structure over a substrate, planarizing the dielectric structure to form a planarized surface, and bonding a first surface of the first redistributing structure to the planarized surface of the dielectric structure, wherein the first redistributing structure is in contact with the dielectric structure.

A method for forming a semiconductor structure is provided in some embodiments of the present disclosure. The method includes forming a first redistributing structure, which includes forming a first sublayer comprising a first dielectric layer and a first conductive feature, polishing a first surface of the first sublayer, and forming a second sublayer over the first surface the first sublayer, wherein the second sublayer includes a second dielectric layer and a second conductive feature. The method further includes forming a dielectric structure over a substrate, and bonding a bottom surface of the first redistributing structure to the dielectric structure.

A semiconductor structure is provided in some embodiments of the present disclosure. The semiconductor structure includes a substrate, a dielectric structure disposed over the substrate, and a first redistributing structure disposed over the dielectric structure, which includes a first sublayer and a second sublayer disposed over the first sublayer, wherein a first interface is between the first sublayer and the second sublayer and has a first peak-to-valley flatness between 5 nm and 100 nm.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for forming a semiconductor structure, comprising:
forming a first redistributing structure over a first carrier;
detaching the first redistributing structure from the first carrier;
forming a dielectric structure over a substrate;
planarizing the dielectric structure to form a planarized surface; and
bonding a first surface of the first redistributing structure to the planarized surface of the dielectric structure, wherein the first redistributing structure is in contact with the dielectric structure.

2. The method as claimed in claim 1, wherein forming the first redistributing structure comprises:
forming a first dielectric layer over a first carrier;
forming a first opening in the first dielectric layer;
forming a first conductive layer over the first dielectric layer and in the first opening; and
planarizing the first conductive layer to expose the first dielectric layer, and the first conductive layer left in the first opening forms a first conductive feature.

3. The method as claimed in claim 2, wherein forming the first redistributing structure further comprises:
forming a second dielectric layer over the first dielectric layer;
forming a second opening in the second dielectric layer, wherein the first conductive feature is partially exposed from the second opening;
forming a second conductive layer over the second dielectric layer and in the second opening; and
planarizing the second conductive layer to expose the second dielectric layer, the second conductive layer left in the second opening forms a second conductive feature, and the second conductive feature is electrically connected to the first conductive feature.

4. The method as claimed in claim 3, further comprising forming a third dielectric layer over the first redistributing structure after bonding the first surface of the first redistributing structure to the planarized surface of the dielectric structure.

5. The method as claimed in claim 1, further comprising:
forming a second redistributing structure over a second carrier;
detaching the second redistributing structure from the second carrier; and
bonding the second redistributing structure to a second surface of the first redistributing structure opposite from the first surface.

6. The method as claimed in claim 1, wherein the first redistributing structure is detached from the first carrier before bonding the first redistributing structure to the dielectric structure.

7. The method as claimed in claim 1, wherein the first redistributing structure is detached from the first carrier after bonding the first redistributing structure to the dielectric structure.

8. A method for forming a semiconductor structure, comprising:
forming a first redistributing structure, comprising:
forming a first sublayer comprising a first dielectric layer and a first conductive feature;
polishing a first surface of the first sublayer; and
forming a second sublayer over the first surface the first sublayer, wherein the second sublayer comprises a second dielectric layer and a second conductive feature;
forming a dielectric structure over a substrate; and
bonding a bottom surface of the first redistributing structure to the dielectric structure.

9. The method as claimed in claim 8, further comprising polishing a top surface of the dielectric structure, wherein the bottom surface of the first redistributing structure is bonded to the top surface of the dielectric structure.

10. The method as claimed in claim 8, wherein forming the first redistributing structure further comprises:
polishing a second surface of the second sublayer; and
forming a third sublayer over the second surface the second sublayer, wherein the third sublayer comprises a third dielectric layer and a third conductive feature, and the third conductive feature is electrically connected to the first conductive feature through the second conductive feature.

11. The method as claimed in claim 8, further comprising forming a conductive element in the dielectric structure, wherein bonding the first redistributing structure to the dielectric structure comprises bonding the first dielectric layer to the dielectric structure, and bonding the first conductive feature to the conductive element.

12. The method as claimed in claim 8, further comprising:
forming a second redistributing structure;
polishing a top surface of the first redistributing structure opposite from the bottom surface; and
bonding the second redistributing structure to the top surface.

13. The method as claimed in claim 8, further comprising forming a third sublayer over the second sublayer after bonding the bottom surface of the first redistributing structure to the dielectric structure, wherein the third sublayer comprises a third dielectric layer and a third conductive feature formed in the third dielectric layer.

14. A semiconductor structure, comprising:
a substrate;
a dielectric structure disposed over the substrate; and
a first redistributing structure disposed over the dielectric structure, comprising:
a first sublayer; and
a second sublayer disposed over the first sublayer, wherein a first interface is between the first sublayer and the second sublayer and has a first peak-to-valley flatness between 5 nm and 100 nm.

15. The semiconductor structure as claimed in claim 14, wherein the first sublayer comprises a first dielectric layer and a first conductive feature disposed in the first dielectric layer, the second sublayer comprises a second dielectric layer and a second conductive feature disposed in the second dielectric layer, wherein the first dielectric layer is bonded to the second dielectric layer, and the first conductive feature is bonded to the second conductive feature.

16. The semiconductor structure as claimed in claim 15, further comprising a second redistributing structure disposed over the first redistributing structure, wherein the second redistributing structure comprises a third sublayer and a fourth sublayer, a second interface is between the third sublayer and the fourth sublayer, and a second peak-to-valley flatness of the second sublayer is greater than the first peak-to-valley flatness.

17. The semiconductor structure as claimed in claim 16, wherein the second redistributing structure is disposed between the first redistributing structure and the dielectric structure.

18. The semiconductor structure as claimed in claim 15, wherein the first conductive feature comprises a via having a vertical sidewall.

19. The semiconductor structure as claimed in claim 14, wherein the first redistributing structure further comprises an alignment mark exposed from a top surface of the first redistributing structure, and the top surface faces away from the dielectric structure.

20. The semiconductor structure as claimed in claim 19, further comprising a second redistributing structure disposed over the first redistributing structure, wherein the alignment mark is covered by the second redistributing structure.
